(19) United States
(12) Patent Application Publication
(10) Pub. No.: US 2025/0031581 A1
(43) Pub. Date: Jan. 23, 2025

(54) MAGNETIC STACKED FILM AND MAGNETORESISTIVE EFFECT ELEMENT

(71) Applicant: TOHOKU UNIVERSITY, Sendai-shi, Miyagi (JP)

(72) Inventors: Yoshiaki Saito, Sendai-shi (JP); Tetsuo Endoh, Sendai-shi (JP); Shoji Ikeda, Sendai-shi (JP)

(73) Assignee: TOHOKU UNIVERSITY, Sendai-shi, Miyagi (JP)

(21) Appl. No.: 18/569,910

(22) PCT Filed: Jun. 15, 2022
(86) PCT No.: PCT/JP2022/024040

§ 371 Date: Aug. 30, 2024

(30) Foreign Application Priority Data
Jun. 15, 2021 (JP) 2021-099796

(51) Int. Cl. H10N 50/10; G11C 11/16; H10B 61/00; H10N 50/85; H10N 52/85

(52) U.S. Cl. CPC H10N 50/10; G11C 11/161; G11C 11/1673; G11C 11/1675; H10B 61/20; H10N 50/85; H10N 52/85

(57) ABSTRACT

There is provided a stacked film that allows flowing a write current and achieves a high-density and/or high-speed memory and a magnetoresistive effect element using the stacked film. A magnetic stacked film 10 is formed of a three-layered structure that includes a first ferromagnetic layer 12, an antiferromagnetic coupling layer 10a provided on the first ferromagnetic layer 12, and a second ferromagnetic layer 16 provided on the antiferromagnetic coupling layer 10a. The antiferromagnetic coupling layer 10a includes a first non-magnetic layer 13, an interlayer coupling layer 14, and a second non-magnetic layer 15. The interlayer coupling layer 14 is selected from a metal or an alloy including at least any one of Ir, Ru, and Rh. The first non-magnetic layer 13 and the second non-magnetic layer 15 are selected from a metal or an alloy including Pt.

### TECHNICAL FIELD

The present invention relates to a magnetic stacked film and a magnetoresistive effect element.

### BACKGROUND ART

Writing information is the key to realize a spintronics integrated circuit. There is a method for electrically reversing magnetization in spintronics, a spin injection magnetization reversal technique. Specifically, a magnetic tunnel junction (MTJ) including: a recording layer having reversible magnetization; a tunnel barrier layer formed of an insulator; and a reference layer in which a magnetization direction is fixed, is supplied with current, reversing magnetization of the recording layer. Recently, a spin-orbit torque (SOT) induced magnetization switching method has been attracting a lot of attention and is being used for electrically reversing magnetization; and the method is applied to a magnetic random access memory (MRAM) element.

A SOT-MRAM element is provided with an MTJ including a recording layer/a tunnel barrier layer/a reference layer formed on a heavy-metal layer. When the heavy-metal layer is supplied with current, the spin-orbit coupling induces a spin current. The spin polarized by the spin Hall effect (spin current) is injected into the recording layer to reverse the magnetization in the recording layer, thereby switching between parallel state and antiparallel state with respect to the magnetization direction in the reference layer; and thus, data is recorded (Patent Literatures 1 to 3).

On the other hand, the following has been reported regarding a magnetoresistive effect of tunnel junction using an antiferromagnetic material using a NiFe/IrMn/MgO/Pt stack configured by providing the antiferromagnetic material on a surface of a tunnel barrier layer and providing a non-magnetic metal on an opposite surface of the tunnel barrier layer (Non-Patent Literature 1). A ferromagnetic moment of NiFe reverses in an external magnetic field, and induces rotation of a bulk antiferromagnetic moment of IrMn that is exchange-coupled to NiFe in association with it. Tunneling anisotropic magnetoresistance (TAMR) effect in association with the rotation of the moment of IrMn is detected.

### CITATION LIST

### Patent Literature

Patent Literature 1: WO 2016/021468 A1
Patent Literature 2: WO 2016/159017 A1
Patent Literature 3: WO 2019/159962 A1

### Non-Patent Literature

Non-Patent Literature 1: Nature Materials, volume 10, pp. 347-351 (2011)

### SUMMARY OF INVENTION

### Technical Problem

With the MRAM using the ferromagnet, influence of a stray magnetic field cannot be ignored in a miniaturization region smaller than 1×nm rule and various malfunctions are expected to occur.

Therefore, one object of the present invention is to provide a magnetic stacked film that allows flowing a write current and achieves a high-density and/or high-speed memory and a magnetoresistive effect element using the magnetic stacked film.

### Solution to Problem

The present invention has the following concepts.
[1] A magnetic stacked film including:
   a first ferromagnetic layer;
   an antiferromagnetic coupling layer provided on the first ferromagnetic layer; and
   a second ferromagnetic layer provided on the antiferromagnetic coupling layer,
   wherein the antiferromagnetic coupling layer includes a first non-magnetic layer and an interlayer coupling non-magnetic layer.
[2] The magnetic stacked film according to [1],
   wherein the antiferromagnetic coupling layer includes the first non-magnetic layer, the interlayer coupling non-magnetic layer provided on the first non-magnetic layer, and a second non-magnetic layer provided on the interlayer coupling non-magnetic layer.
[3] The magnetic stacked film according to [1] or [2],
   wherein the first non-magnetic layer is made of a metal or an alloy including Pt.
[4] The magnetic stacked film according to any one of [1] to [3].
   wherein the interlayer coupling non-magnetic layer is made of a metal or an alloy including at least any one of Ir, Rh, and Ru.
[5] The magnetic stacked film according to any one of [1] to [4],
   wherein respective magnetizations of the first ferromagnetic layer and the second ferromagnetic layer reverse by a spin-orbit torque caused by current.
[6] The magnetic stacked film according to any one of [1] to [5].
   wherein a third non-magnetic layer is provided on an opposite surface of the antiferromagnetic coupling layer of the first ferromagnetic layer and/or an opposite surface of the antiferromagnetic coupling layer of the second ferromagnetic layer, and the third non-magnetic layer is made of a metal or an alloy including at least any one of W, Cu, Ta, and Mn.
[7] A magnetoresistive effect element including:
   the magnetic stacked film according to any one of [1] to [6];
   a recording layer that includes a ferromagnetic layer or an antiferromagnetic layer and is provided on the magnetic stacked film;
   a tunnel barrier layer made of an insulating materials and provided on the recording layer; and
   a reference layer provided on the tunnel barrier layer,
   wherein the first ferromagnetic layer or the second ferromagnetic layer of the magnetic stacked film and the ferromagnetic layer or the antiferromagnetic layer of the recording layer are coupled by exchange interaction, and
   wherein, by flowing current in a direction intersecting with a stacking direction of the magnetic stacked film, respective magnetizations in the first ferromagnetic layer and the second ferromagnetic layer reverse to reverse magnetization of the recording layer.
[8] The magnetoresistive effect element according to [7],
   wherein the reference layer is formed of a non-magnetic layer.
[9] The magnetoresistive effect element according to [7],
   wherein the reference layer includes a magnetic layer in which magnetization is fixed.
[10] The magnetoresistive effect element according to any one of [7] to [9],
   wherein the magnetic stacked film includes a third non-magnetic layer on a surface of the recording layer or an opposite surface of the recording layer, and
   wherein the third non-magnetic layer is made of a metal or an alloy including at least any one of W, Cu, Ta, and Mn.
[11] The magnetoresistive effect element according to any one of [7] to [9],
   wherein the magnetic stacked film includes a third non-magnetic layer on a surface of the recording layer and a fourth non-magnetic layer on an opposite surface of the recording layer, and
   wherein the third non-magnetic layer and the fourth non-magnetic layer are made of a metal or an alloy including at least any one of W, Cu, Ta, and Mn.
[12] A magnetoresistive effect element including:
   a conductive layer that includes a first ferromagnetic layer, an antiferromagnetic coupling layer provided on the first ferromagnetic layer, and a second ferromagnetic layer provided on the antiferromagnetic coupling layer, the antiferromagnetic coupling layer including a first non-magnetic layer and an interlayer coupling non-magnetic layer;
   a recording layer provided on the conductive layer;
   a tunnel barrier layer provided on the recording layer; and
   a reference layer provided on the tunnel barrier layer,
   wherein the conductive layer includes a third non-magnetic layer provided on a surface of the recording layer or an opposite surface of the recording layer, and the third non-magnetic layer is made of a metal or an alloy including at least any one of W, Cu, Ta, and Mn.
[13] The magnetoresistive effect element according to [12],
   wherein any one of the first ferromagnetic layer and the second ferromagnetic layer that is in contact with the third non-magnetic layer has a magnetization inclined in a direction of current application of the conductive layer.
[14] A magnetic stacked film including:
   a first ferromagnetic layer;
   an antiferromagnetic coupling layer provided on the first ferromagnetic layer; and
   a second ferromagnetic layer provided on the antiferromagnetic coupling layer,
   wherein the first ferromagnetic layer and the second ferromagnetic layer are antiferromagnetically coupled,
   wherein the antiferromagnetic coupling layer includes a first non-magnetic layer and an interlayer coupling non-magnetic layer,
   wherein the first non-magnetic layer is made of a metal or an alloy including Pt, and
   wherein the interlayer coupling non-magnetic layer is made of a metal or an alloy including at least any one of Ir, Rh, and Ru.
[15] A magnetic stacked film including:
   a first ferromagnetic layer;
   an antiferromagnetic coupling layer provided on the first ferromagnetic layer; and
   a second ferromagnetic layer provided on the antiferromagnetic coupling layer,
   wherein the first ferromagnetic layer and the second ferromagnetic layer are antiferromagnetically coupled,
   wherein the antiferromagnetic coupling layer includes a first non-magnetic layer, the interlayer coupling non-magnetic layer provided on the first non-magnetic layer, and a second non-magnetic layer provided on the interlayer coupling non-magnetic layer,
   wherein the first non-magnetic layer and the second non-magnetic layer are made of a metal or an alloy including Pt, and
   wherein the interlayer coupling non-magnetic layer is made of a metal or an alloy including at least any one of Ir, Rh, and Ru.
[16] The magnetic stacked film according to [14] or [15],
   wherein a third non-magnetic layer is provided on a surface opposite to the antiferromagnetic coupling layer of the first ferromagnetic layer and/or a surface opposite to the antiferromagnetic coupling layer of the second ferromagnetic layer, and the third non-magnetic layer is made of a metal or an alloy including at least any one of W, Cu, Ta, and Mn.

### Advantageous Effects of Invention

According to the present invention, the magnetic stacked film that allows flowing a write current and achieves a high-density and/or high-speed memory and a magnetoresistive effect element using the magnetic stacked film can be provided.

### BRIEF DESCRIPTION OF DRAWINGS

FIG. 1A is a plan view of a magnetic stacked film and a magnetoresistive effect element using the magnetic stacked film according to a first embodiment of the present invention.

FIG. 1B is a sectional view taken along the line A-A in FIG. 1A.

FIG. 2A is a diagram for describing a state in which current flows to the magnetic stacked film according to the first embodiment of the present invention to write data “0” in a recording layer.

FIG. 2B is a diagram for describing a state in which current flows to the magnetic stacked film according to the first embodiment of the present invention in an inverse direction to write data “1” in the recording layer.

FIG. 3A is a plan view of a magnetic stacked film and a magnetoresistive effect element using the magnetic stacked film according to a second embodiment of the present invention.

FIG. 3B is a sectional view taken along the line B-B in FIG. 3A.

FIG. 3C is a sectional view in a different viewpoint of the magnetic stacked film and the magnetoresistive effect element according to the second embodiment of the present invention.

FIG. 3D is a different sectional view of the magnetic stacked film and the magnetoresistive effect element according to the second embodiment of the present invention.

FIG. 4A is a plan view of a magnetic stacked film and a magnetoresistive effect element using the magnetic stacked film according to a third embodiment of the present invention.

FIG. 4B is a sectional view taken along the line C-C in FIG. 4A.

FIG. 5A is a diagram for describing a state in which current flows to the magnetic stacked film according to the third embodiment of the present invention to write data “O” in a recording layer.

FIG. 5B is a diagram for describing a state in which current flows to the magnetic stacked film according to the third embodiment of the present invention in an inverse direction to write data “1” in the recording layer.

FIG. 6A is a plan view of a magnetic stacked film and a magnetoresistive effect element using the magnetic stacked film according to a fourth embodiment of the present invention.

FIG. 6B is a sectional view taken along the line D-D in FIG. 6A.

FIG. 6C is a sectional view in a different viewpoint of the magnetic stacked film and the magnetoresistive effect element according to the fourth embodiment of the present invention.

FIG. 6D is a different sectional view of the magnetic stacked film and the magnetoresistive effect element according to the fourth embodiment of the present invention.

FIG. 7 is magnetization curves of a sample of Demonstrative Example 1.

FIG. 8 is magnetization curves of a sample of Demonstrative Example 2.

FIG. 9 is magnetization curves of a sample of Demonstrative Example 3.

FIG. 10 is a graph illustrating the dependence of the interlayer exchange coupling Jₑₓ (mJ/m²) on the total film thickness tₜₒₜₐₗ (nm) of non-magnetic layers.

FIG. 11 is magnetization curves of a sample of Demonstrative Example 5.

FIG. 12 is magnetization curves of a sample of Demonstrative Example 6.

FIG. 13 is magnetization curves of a sample of Demonstrative Example 7.

FIG. 14 is magnetization curves of a sample of Demonstrative Example 8.

FIG. 15 is a graph illustrating the dependence of the interlayer exchange coupling Jₑₓ (mJ/m²) on the total film thickness tₜₒₜₐₗ (nm) of non-magnetic layers.

FIG. 16 is the dependence of the interlayer exchange coupling Jₑₓ on the Ir layer thickness.

FIG. 17 is the dependence of the interlayer exchange coupling Jₑₓ on the Ru layer thickness.

FIG. 18 is a diagram schematically illustrating a Hall bar and a measurement system that were fabricated as Sample 29.

FIG. 19A is a sectional view of the fabricated Sample 29.

FIG. 19B is a sectional view of a fabricated sample of Comparative Example 2.

FIG. 20 is a result plotting the dependence of the Hall resistivity Rxy (Ω) on the pulse current in samples of Sample 29 and Comparative Example 2.

FIG. 21A is a result plotting the dependence of the spin-orbit torque efficiency on the Ir layer thickness regarding Sample 30 to Sample 34.

FIG. 21B is a result plotting the dependence of the spin-orbit torque efficiency on the interlayer exchange coupling Jₑₓ (mJ/m²) regarding Sample 30 to Sample 34.

FIG. 22A is a result plotting the dependence of the spin-orbit torque efficiency on the Pt layer thickness regarding Sample 35 to Sample 39.

FIG. 22B is a result plotting the dependence of the spin-orbit torque efficiency on the interlayer exchange coupling Jₑₓ (mJ/m²) regarding Sample 35 to Sample 39.

FIG. 23A is a plan view of a magnetoresistive effect element according to a fifth embodiment.

FIG. 23B is a sectional view taken along the line E-E in FIG. 23A.

FIG. 24 is a sectional view of a magnetoresistive effect element according to a sixth embodiment.

FIG. 25 is a sectional view of a magnetoresistive effect element according to a seventh embodiment.

FIG. 26 is a sectional view of Demonstrative Example 10.

FIG. 27 is an electron microscope image of a Hall bar fabricated in Demonstrative Example 10.

FIG. 28A is a diagram illustrating a result of the dependence of the Hall resistivity Rxy (Ω) on the pulse current in Demonstrative Example 10 when the pulse current I=200 μsec was applied and a constant external magnetic field Hex=49 mT and 39 mT were applied, respectively, in a direction of the pulse current I (φ=0 degree direction in FIG. 18) during measurement.

FIG. 28B is a diagram illustrating a result of the dependence of the Hall resistivity Rxy (Ω) on the pulse current in Demonstrative Example 10 when the pulse current I=200 μsec was applied and the constant external magnetic field Hex=28.5 mT and 18 mT were applied, respectively, in the direction of the pulse current I (φ=0 degree direction in FIG. 18) during measurement.

FIG. 28C is a diagram illustrating a result of the dependence of the Hall resistivity Rxy (Ω) on the pulse current in Demonstrative Example 10 when the pulse current I=200 μsec was applied and the constant external magnetic field Hex=8 mT and 0 mT were applied, respectively, in the direction of the pulse current I (φ=0 degree direction in FIG. 18) during measurement.

FIG. 28D is a diagram illustrating a result of the dependence of the Hall resistivity Rxy (Ω) on the pulse current in Demonstrative Example 10 when the pulse current I=200 μsec was applied and the constant external magnetic field Hex=−6.5 mT and −16.5 mT were applied, respectively, in the direction of the pulse current I (φ=0 degree direction in FIG. 18) during measurement.

FIG. 28E is a diagram illustrating a result of the dependence of the Hall resistivity Rxy (Ω) on the pulse current in Demonstrative Example 10 when the pulse current I=200 μsec was applied and the constant external magnetic field Hex=−27 mT and −37 mT were applied, respectively, in the direction of the pulse current I (@=0 degree direction in FIG. 18) during measurement.

FIG. 28F is a diagram illustrating a result of the dependence of the Hall resistivity Rxy (Ω) on the pulse current in Demonstrative Example 10 when the pulse current I=200 μsec was applied and the constant external magnetic field Hex=−48 mT and −58 mT were applied, respectively, in the direction of the pulse current I (φ=0 degree direction in FIG. 18) during measurement.

FIG. 29 is a diagram illustrating the dependence of the Hall resistivity Rxy (Ohm) on the number of repetitions when the pulse currents were alternately applied in the ±directions in a magnetic field Hex=0 mT in Demonstrative Example 10.

FIG. 30 is a diagram illustrating a result of the dependence of the Hall resistivity Rxy (Ω) on the pulse current in Demonstrative Example 11 when the pulse current I=200 μsec and the external magnetic field Hex=0 mT during measurement.

FIG. 31 is a diagram illustrating the dependence of the Hall resistivity Rxy (Ohm) on the number of repetitions when the pulse currents were alternately applied in the ±directions in a magnetic field Hex=0 mT in Demonstrative Example 11.

FIG. 32 is a sectional view of Demonstrative Example 12.

FIG. 33 is a result plotting the dependence of the Hall resistivity Rxy (Ω) on the pulse current in Comparative Example 12.

FIG. 34 is a diagram illustrating the dependence of the Hall resistivity Rxy (Ω) on the pulse current in Demonstrative Example 13.

FIG. 35 is a diagram illustrating the dependence of the Hall resistivity Rxy (Ω) on the pulse current in Demonstrative Example 14.

FIG. 36 is a diagram illustrating the dependence of the Hall resistivity Rxy (Ω) on the pulse current in Demonstrative Example 15.

FIG. 37 is a diagram illustrating the dependence of the Hall resistivity Rxy (Ω) on the pulse current in Demonstrative Example 16.

FIG. 38 is a diagram illustrating the dependence of the Hall resistivity Rxy (Ohm) on the number of repetitions when the pulse currents were alternately applied in the ±directions in a magnetic field Hex=0 mT in Demonstrative Example 16.

FIG. 39 is a result plotting the dependence of the Hall resistivity Rxy (Ω) on the pulse current in Comparative Example 3.

FIG. 40 is a sectional view of Comparative Example 4.

FIG. 41A is a result plotting the dependence of the Hall resistivity Rxy (Ω) on the pulse current in Comparative Example 4 when the pulse current I=200 μsec was applied and the constant external magnetic field Hex=29 mT was applied in the direction of the pulse current I (φ=0 degree direction in FIG. 18) during measurement.

FIG. 41B is a result plotting the dependence of the Hall resistivity Rxy (Ω) on the pulse current in Comparative Example 4 when the pulse current I=200 μsec was applied and the constant external magnetic field Hex=0 mT during measurement.

FIG. 41C is a result plotting the dependence of the Hall resistivity Rxy (Ω) on the pulse current in Comparative Example 4 when the pulse current I=200 μsec was applied and the constant external magnetic field Hex=−27 mT was applied in the direction of the pulse current I (φ=0 degree direction in FIG. 18) during measurement.

### DESCRIPTION OF EMBODIMENTS

The embodiments of the present invention will now be described in detail with reference to the drawings. Those matters described in the embodiments of the present invention can be appropriately modified without departing from the scope of the present invention.

### First Embodiment

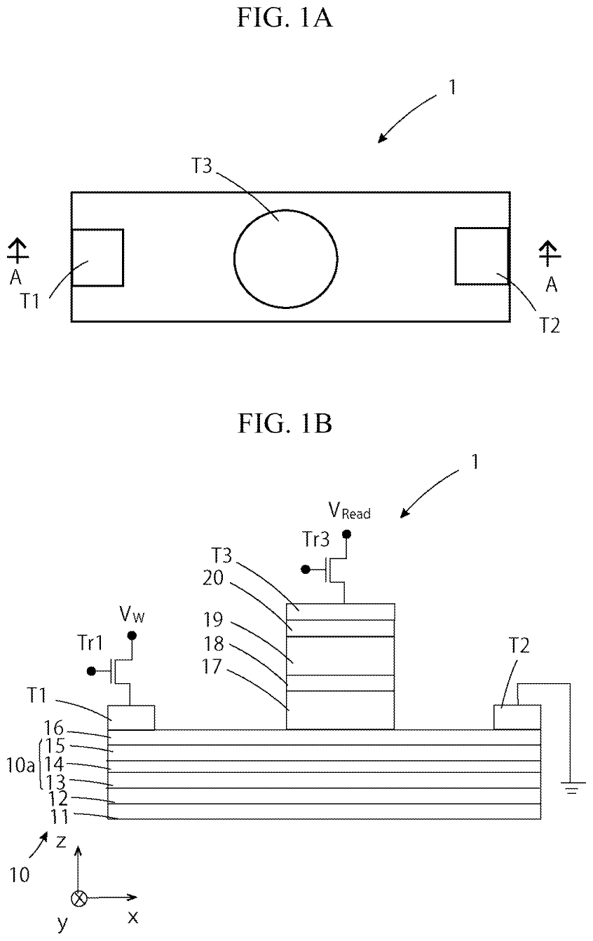

FIG. 1A is a plan view of a magnetic stacked film and a magnetoresistive effect element using the magnetic stacked film according to the first embodiment of the present invention. FIG. 1B is a sectional view taken along the line A-A. As illustrated in FIG. 1A and FIG. 1B, a magnetic stacked film 10 according to the first embodiment of the present invention includes an underlayer 11 provided on a substrate (not illustrated), a first ferromagnetic layer 12 provided on the underlayer 11, a first non-magnetic layer 13 provided on the first ferromagnetic layer 12, an interlayer coupling layer 14 provided on the first non-magnetic layer 13, a second non-magnetic layer 15 provided on the interlayer coupling layer 14, and a second ferromagnetic layer 16 provided on the second non-magnetic layer 15. That is, the magnetic stacked film 10 is configured as follows. The interlayer coupling layer 14 is interposed between the first non-magnetic layer 13 and the second non-magnetic layer 15 in contact with corresponding upper surface and lower surface of the interlayer coupling layer 14. The first non-magnetic layer 13, the interlayer coupling layer 14, and the second non-magnetic layer 15 are interposed between the first ferromagnetic layer 12 and the second ferromagnetic layer 16 in contact with corresponding lower surface of the first non-magnetic layer 13 and upper surface of the second non-magnetic layer 15. The first ferromagnetic layer 12 is provided in contact with the lower surface of the first non-magnetic layer 13, and the second ferromagnetic layer 16 is provided in contact with the upper surface of the second non-magnetic layer 15. In the illustrated example, on the second ferromagnetic layer 16, a recording layer 17 made of a material that allows magnetization reversal is formed. In the first embodiment, the first non-magnetic layer 13, the interlayer coupling layer 14, and the second non-magnetic layer 15 constitute an antiferromagnetic coupling layer 10a. The interlayer coupling layer 14 may be referred to as an interlayer coupling non-magnetic layer. The antiferromagnetic coupling layer 10a includes the first non-magnetic layer 13, the interlayer coupling non-magnetic layer (interlayer coupling layer 14) provided on the first non-magnetic layer 13, and the second non-magnetic layer 15 provided on the interlayer coupling non-magnetic layer.

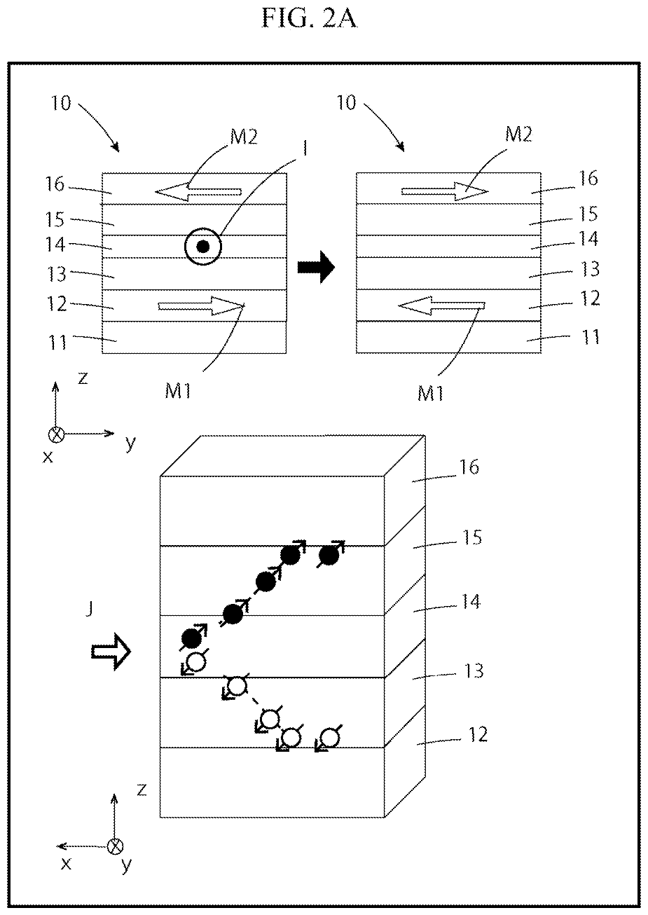

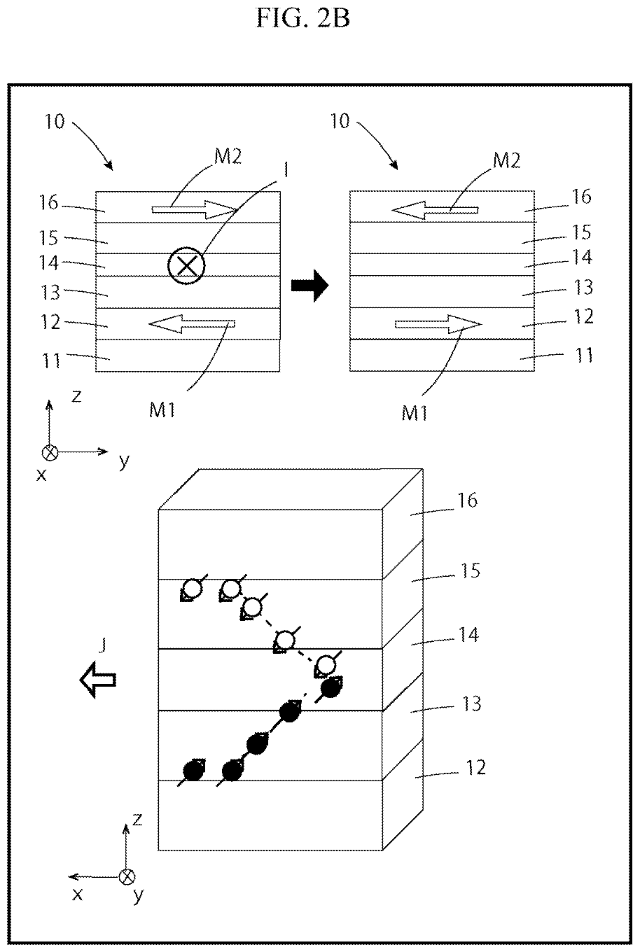

FIG. 2A is a diagram for describing a state in which current flows to the magnetic stacked film 10 according to the first embodiment of the present invention to write data “0” in the recording layer 17. As illustrated in FIG. 2A, before current flows in a −x direction, magnetizations are in inverse directions from one another between the first ferromagnetic layer 12 and the second ferromagnetic layer 16. By flowing current to the magnetic stacked film 10 in the −x direction, a spin current (a flow of a spin motion) occurs by the spin Hall effect due to the spin-orbit interaction. The respective spins in the inverse directions from one another flow in the corresponding directions in the ±z directions of the magnetic stacked film 10, by the spin currents flowing through the magnetic stacked film 10, the respective spin in one direction and spin in the other direction separately flow to the up and the down, and the spins are accumulated on an interface between the first ferromagnetic layer 12 and the first non-magnetic layer 13 and an interface between the second non-magnetic layer 15 and the second ferromagnetic layer 16 and are absorbed to the respective first ferromagnetic layer 12 and second ferromagnetic layer 16. Therefore, as illustrated in FIG. 2A, magnetizations M1 and M2 of the first ferromagnetic layer 12 and the second ferromagnetic layer 16 are in the inverse directions of the directions before current I flows. Thus, flowing the current to the magnetic stacked film 10 in the −x direction generates a spin-orbit torque caused by the current, and the respective magnetizations of the first ferromagnetic layer 12 and the second ferromagnetic layer 16 are switched.

Here, in the first embodiment of the present invention, since the interlayer coupling layer 14 is interposed between the first non-magnetic layer 13 and the second non-magnetic layer 15 in the magnetic stacked film 10, compared with a case of not being interposed, the spin torque increases, and magnetization of the respective first ferromagnetic layer 12 and second ferromagnetic layer 16 can be switched. According to the first embodiment of the present invention, since the two layers of the ferromagnetic layers are present in the magnetic stacked film 10 illustrated in FIG. 2A and they are antiferromagnetically coupled, thermal stability constant Δ can be increased. Additionally, in the conventional SOT element, since the first ferromagnetic layer 12 has been absent at the lower portion, only a spin current accumulated on the interface between the second ferromagnetic layer 16 and the second non-magnetic layer 15 has been utilized for magnetization reversal. With the stacked structure according to the first embodiment of the present invention, not only the spin current accumulated on the interface between the second ferromagnetic layer 16 and the second non-magnetic layer 15 generated when a current pulse flows, but also the spin current accumulated on the interface between the first ferromagnetic layer 12 and the first non-magnetic layer 13 can be utilized, and therefore reverse energy efficiency can be increased to the extent of double.

Provisionally, in the magnetic stacked film 10, when the first non-magnetic layer 13 or the second non-magnetic layer 15 is not provided and the interlayer coupling layer 14 is directly interposed between the first ferromagnetic layer 12 and the second ferromagnetic layer 16, even when the interlayer coupling layer 14 is made of Ru or Ir and antiferromagnetic coupling is achieved, since spin Hall angles of Ru and Ir are considerably small, achieving magnetization reversal by the spin Hall effect is considerably difficult. However, with this structure, since the large spin Hall effect of the first non-magnetic layer 13 and the second non-magnetic layer 15 can be used, compared with a case of not providing the first non-magnetic layer 13 or the second non-magnetic layer 15, inversion current of the spin can be significantly reduced.

FIG. 2B is a diagram for describing a state in which current flows to the magnetic stacked film 10 according to the first embodiment of the present invention in an inverse direction to write data “1” in the recording layer 17. As illustrated in FIG. 2B, before current flows in a +x direction as the inverse direction, magnetizations are in inverse directions from one another between the first ferromagnetic layer 12 and the second ferromagnetic layer 16. By flowing current to the magnetic stacked film 10 in the +x direction, a spin current (a flow of a spin motion) occurs by the spin Hall effect due to the spin-orbit interaction. The respective spins in the inverse directions from one another flow in the corresponding directions in the ±z directions (here, the inverse directions compared with the case of FIG. 2A) of the magnetic stacked film 10, by the spin currents flowing through the magnetic stacked film 10, the respective spin in one direction and spin in the other direction separately flow to the up and the down, and the spins flow toward the respective first ferromagnetic layer 12 and second ferromagnetic layer 16. Therefore, as illustrated in FIG. 2B, the respective magnetizations M1 and M2 of the first ferromagnetic layer 12 and the second ferromagnetic layer 16 are in the inverse directions of the directions before the current flows in the +x direction. Thus, flowing the current to the magnetic stacked film 10 in the +x direction generates a spin-orbit torque caused by the current, and the respective magnetizations of the first ferromagnetic layer 12 and the second ferromagnetic layer 16 are switched.

Here, similar to the case where antiferromagnetic coupling is kept in the magnetic stacked film of the first ferromagnetic layer/the interlayer coupling layer/the second ferromagnetic layer, as in the first embodiment of the present invention, antiferromagnetic coupling is kept by the interlayer coupling layer 14 being interposed between the first non-magnetic layer 13 and the second non-magnetic layer 15 as the magnetic stacked film 10. This will be described in Demonstrative Examples described later.

While FIG. 2A and FIG. 2B illustrate the case of in-plane magnetization, the same applies to a case of perpendicular magnetization.

As one utilization aspect of the magnetic stacked film 10, the description will be continued with an example of a magnetoresistive effect element 1. The magnetic stacked film 10 has a surface of providing a reading antiferromagnetic layer as the recording layer 17 on the second ferromagnetic layer 16 and the recording layer 17 having reversible magnetization is provided. The reading bulk antiferromagnetic layer is preferably an Ir—Mn alloy, an Fe—Mn alloy, and the like. On the recording layer 17, a barrier layer (also referred to as a tunnel barrier layer) 18 is provided to be in contact with the recording layer 17. The tunnel barrier layer 18 is preferably made of an insulating material, such as MgO, Al₂O₃, AlN, and MgAlO, and epitaxially grown on the Ir—Mn alloy and the Fe—Mn alloy. On the tunnel barrier layer 18, a non-magnetic layer 19 as a reference layer is provided. The non-magnetic layer 19 is not especially limited, but is preferably Pt, Al, Cu, and the like. Stacking the recording layer 17, the tunnel barrier layer 18, and the non-magnetic layer 19 constitutes the magnetoresistive effect element 1 using a tunneling anisotropic magnetoresistance (TAMR) effect. Here, the reading antiferromagnetic layer as the recording layer 17 and the second ferromagnetic layer 16 are coupled by an exchange coupling action, the antiferromagnetic moment in the reading antiferromagnetic layer rotates by magnetization reversal in the second ferromagnetic layer 16, and therefore the magnitude of the resistance differs significantly.

On either of the uppermost surface and the lowermost surface of the magnetic stacked film 10, a first terminal T1 and a second terminal T2 are provided, and the first terminal T1 and the second terminal T2 are separated in a direction perpendicular to the stacking direction of the magnetic stacked film 10. The write current flows between the first terminal T1 and the second terminal T2. On the non-magnetic layer 19, a cap layer 20 is provided and a third terminal T3 is provided, and a read current can be applied to the third terminal T3. In FIG. 1B, one end of a transistor Tr1 is connected to the first terminal T1, the second terminal T2 is grounded, and when the transistor Tr1 is turned ON and a write voltage V_{W} is applied, the current flows in the x direction. One end of a transistor Tr3 is connected to the second terminal T2, and when the transistor Tr3 is turned ON and a read voltage V_{Read} is applied, the current flows from the third terminal T3 to the second terminal T2.

Here, the reading antiferromagnetic layer as the recording layer 17 and the second ferromagnetic layer 16 are coupled by exchange coupling action, and the antiferromagnetic moment in the reading antiferromagnetic layer rotates by magnetization reversal in the second ferromagnetic layer 16. In association with the change in the direction of the antiferromagnetic magnetic moment, the resistance differs significantly, and therefore the recording layer 17 can be read.

Accordingly, since the magnitude of the read current differs, flowing current to the third terminal T3 allows determining whether the data recorded in a reading bulk antiferromagnetic layer as the recording layer 17 is “0” or “1.”

Next, the specific material of the magnetic stacked film 10 will be described. The interlayer coupling layer 14 is made of a metal or an alloy including at least any one of Ir, Rh, and Ru. When Ir is included, the thickness may be in a range from 0.4 nm or more and 0.7 nm or less. In the case of Ru, the thickness may be in a range from 0.6 nm or more and 0.9 nm or less. The interlayer coupling layer 14 is preferably made of a metal or an alloy having an fcc structure including at least any one of Ir and Rh. The interlayer coupling layer 14 is especially preferably made of a metal or an alloy having an fcc structure including any one of Ir, an Ir—Os alloy, Rh, an Ir—Rh alloy, an Ir—Re alloy, and an Ir—Ru alloy.

The first non-magnetic layer 13 and the second non-magnetic layer 15 are made of a metal or an alloy including Pt. The first non-magnetic layer 13 and the second non-magnetic layer 15 are preferably made of a metal or an alloy having an fcc structure including Pt. The first non-magnetic layer 13 and the second non-magnetic layer 15 are especially preferably selected from a metal and an alloy having an fcc structure of any of Pt, a Pt—Au alloy, a Pt—Ir alloy, a Pt—Cu alloy, and a Pt—Cr alloy. The first non-magnetic layer 13 and the second non-magnetic layer 15 may be a Pt—Pd alloy, a Pt—Hf alloy, and a Pt—Al alloy.

In the magnetic stacked film 10 according to the first embodiment of the present invention, even when the interlayer coupling layer 14 is interposed between the first non-magnetic layer 13 and the second non-magnetic layer 15, the first ferromagnetic layer 12 and the second ferromagnetic layer 16 are antiferromagnetically coupled. Therefore, a structure in which a stray magnetic field does not occur in the magnetic stacked film 10 itself is employed, and thermal stability is satisfactory. For formation of further perfect antiferromagnetic coupling, the first ferromagnetic layer 12 and the second ferromagnetic layer 16 preferably have the same thickness.

As described above, the use of the magnetic stacked film 10 as a write control layer of the magnetoresistive effect element 1 using the SOT further improves write efficiency. Additionally, the use of the magnetic stacked film 10 with such antiferromagnetic coupling improves a write speed faster.

The magnetoresistive effect element 1 according to the first embodiment of the present invention includes the reading bulk antiferromagnetic layer as the recording layer 17 that couples by exchange interaction, which is provided on the second ferromagnetic layer 16, the tunnel barrier layer 18 provided on the reading bulk antiferromagnetic layer, and a fixed layer formed of the non-magnetic layer 19. Since the recording layer 17 couples by magnetization and exchange interaction of the second ferromagnetic layer 16, the structure does not cause a stray magnetic field. Accordingly, the magnetoresistive effect element 1 itself does not cause a stray magnetic field. Additionally, the thermal stability is determined by the volume of the magnetic material of the magnetic stacked film 10. Therefore, as illustrated in FIG. 1B, since the volume of the magnetic material presents in the entire lower electrode rather than a read element including the recording layer 17, the tunnel barrier layer 18, the non-magnetic layer 19 as the reference layer, the cap layer 20, and the terminal T3, which is found to be considerably satisfactory.

In view of this, by disposing a plurality of stacks on at least one magnetic stacked film 10, each stack including the reading bulk antiferromagnetic layer as the recording layer 17/the tunnel barrier layer 18/the fixed layer formed of the non-magnetic layer 19, even when the stacks are integrated as a magnetic memory device, such as an MRAM, incorrect writing and incorrect reading due to a stray magnetic field decrease as much as possible.

In the magnetic stacked film 10 and the magnetoresistive effect element 1 according to the first embodiment, the first ferromagnetic layer 12 and the second ferromagnetic layer 16 may employ any of in-plane magnetization and perpendicular magnetization. As illustrated in FIG. 2A, in the case of in-plane magnetization, an axis of easy magnetization is not limited to be in a direction perpendicular to the direction of the current I, and the axis of easy magnetization may be any of the x direction, y direction, and an xy direction inclined in the x direction and the y direction inside an xy plane. That is, for example, a type Y in which the axis of easy magnetization and the spin are parallel/antiparallel or a type X and a type Z in which a direction of easy magnetization and the spin are perpendicular to one another may be employed.

### Second Embodiment

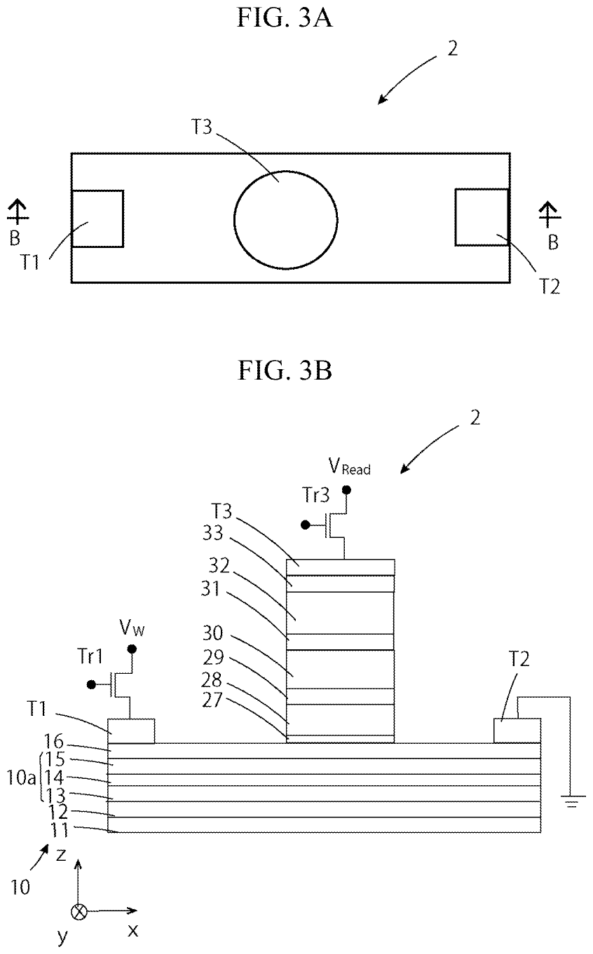

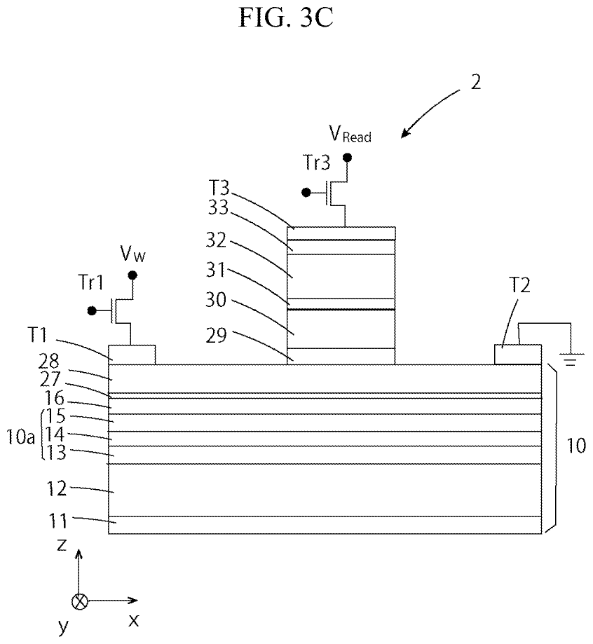

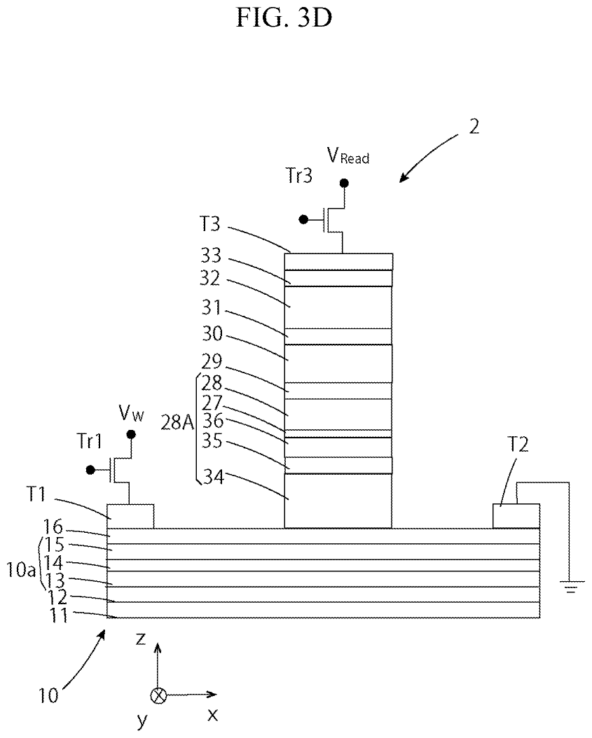

FIG. 3A is a plan view of a magnetic stacked film and a magnetoresistive effect element using the magnetic stacked film according to the second embodiment of the present invention. FIG. 3B is a sectional view taken along the line B-B. The magnetic stacked film 10 according to the second embodiment of the present invention has the configuration similar that of the first embodiment, and thus has the similar effects as the first embodiment. The detailed description is overlapped and therefore is omitted.

In the second embodiment, a recording layer 28 configured including the ferromagnetic layer is provided above the second ferromagnetic layer 16 between which a non-magnetic layer 27 is interposed to separate crystalline structures of the recording layer 28 and the second ferromagnetic layer 16. Examples of the ferromagnetic layer as the recording layer 28 include CoFeBo, FeB, and CoB. A tunnel barrier layer 29 is provided to be in contact with a reference layer 30. A non-magnetic layer 31 is provided on an opposite surface of the reference layer 30 adjacent to the tunnel barrier layer 29 to separate crystalline structures of upper and lower layers of the non-magnetic layer 31. One or more elements, such as W, Ta, Mo, and Hf, are selected as the non-magnetic layer 27 and the non-magnetic layer 31.

Additionally, on the opposite surface of the reference layer 30 between which the non-magnetic layer 31 is interposed, for example, in the case of a perpendicular magnetization film, an anchoring layer 32 made of (Co/Pt) m/Ir/(Co/Pt) n is provided and in the case of an in-plane magnetization film, the anchoring layer 32 made of CoFe/Ru/CoFe/IrMn is provided to fix and pin the magnetization direction of the ferromagnetic layer in the reference layer 30. In this case, the ferromagnetic layer and the anchoring layer may be collectively referred to as the reference layer. The above-described m and n are any natural number. A cap layer 33 is provided on an opposite surface of the non-magnetic layer 31 of the anchoring layer 32, and the third terminal T3 is mounted to the cap layer 33. The third terminal T3 is connected to the transistor Tr3.

In a magnetoresistive effect element 2 according to the second embodiment of the present invention, on the second ferromagnetic layer 16, what is called an MTJ element including the ferromagnetic layer as the recording layer 28 coupled by exchange interaction, the tunnel barrier layer 29 provided on the recording layer 28, and the reference layer 30 is configured.

On either of the uppermost surface and the lowermost surface of the magnetic stacked film 10, the first terminal T1 and the second terminal T2 are provided, and the first terminal T1 and the second terminal T2 are separated in a direction perpendicular to the stacking direction of the magnetic stacked film 10. The write current flows between the first terminal T1 and the second terminal T2.

In the magnetic stacked film 10 according to the second embodiment, flowing current between the first terminal T1 and the second terminal T2 allows writing data similarly to the first embodiment, and therefore the description will be omitted. To read data, by flowing current to the third terminal T3, whether the magnetization of the recording layer 28 is parallel to or antiparallel to the magnetization of the reference layer 30 can be determined from the magnitude of the current flowing through the recording layer 28, the tunnel barrier layer 29, and the reference layer 30, which constitute the MTJ element, and data can be read.

In the magnetic stacked film 10 according to the second embodiment of the present invention, even when the interlayer coupling layer 14 is interposed between the first non-magnetic layer 13 and the second non-magnetic layer 15, the first ferromagnetic layer 12 and the second ferromagnetic layer 16 are antiferromagnetically coupled. Therefore, a structure in which a stray magnetic field does not occur in the magnetic stacked film 10 itself is employed. Since the two layers of the ferromagnetic layers are present and they are antiferromagnetically coupled, the thermal stability constant Δ can be increased. Additionally, in the conventional SOT element, since the first ferromagnetic layer 12 has been absent at the lower portion, only a spin current accumulated on the interface between the second ferromagnetic layer 16 and the second non-magnetic layer 15 has been utilized for magnetization reversal. With the stacked structure, not only the spin current accumulated on the interface between the second ferromagnetic layer 16 and the second non-magnetic layer 15 generated when a current pulse flows, but also the spin current accumulated on the interface between the first ferromagnetic layer 12 and the first non-magnetic layer 13 can be utilized, and therefore reverse energy efficiency can be increased to the extent of double. With this structure, since the large spin Hall effect of the first non-magnetic layer 13 and the second non-magnetic layer 15 can be used, compared with a case of not providing the first non-magnetic layer 13 or the second non-magnetic layer 15, inversion current of the spin can be significantly reduced. For formation of further perfect antiferromagnetic coupling, the first ferromagnetic layer 12 and the second ferromagnetic layer 16 preferably have the same thickness.

The use of the magnetic stacked film 10 as a write control layer of the magnetoresistive effect element 2 using the SOT further improves write efficiency. The use of the magnetic stacked film 10 with such antiferromagnetic coupling improves a write speed faster.

In the magnetoresistive effect element 2 according to the second embodiment of the present invention, on the second ferromagnetic layer 16, what is called an MTJ element including the ferromagnetic layer as the recording layer 28 coupled by exchange interaction, the tunnel barrier layer 29 provided on the recording layer 28, and the reference layer 30 is configured. FIG. 3C is a sectional view in a different viewpoint of the magnetic stacked film 10 and the magnetoresistive effect element 2 according to the second embodiment of the present invention. As illustrated in FIG. 3C, as a structure of further decreasing a stray magnetic field, it is preferable that the layers up to the recording layer 28 are configured as the magnetic stacked film 10 and values of the magnetization of the first ferromagnetic layer 12 and the magnetization of the second ferromagnetic layer 16/the non-magnetic layer 27/the recording layer 28 are canceled. FIG. 3D is a different sectional view of the magnetic stacked film 10 and the magnetoresistive effect element 2 according to the second embodiment of the present invention. As illustrated in FIG. 3D, an entire Co layer 34/Ir layer 35/Co layer 36/non-magnetic layer 27/recording layer 28 with the recording layer structure being the antiferromagnetic coupling structure may be configured as a recording layer 28A. The Co layers 34 and 36 may be ferromagnetic layers other than Co. The Ir layer 35 is not limited thereto but may be, for example, an Ru layer made of a material of the interlayer coupling layer. Adjusting thicknesses of films constituting the reference layer 30 and the anchoring layer 32 allows avoiding a stray magnetic field. Accordingly, the magnetoresistive effect element 2 itself does not cause a leakage of a stray magnetic field.

In view of this, by disposing a plurality of what is called MTJ elements, each element including the ferromagnetic layer as the recording layer 28, the tunnel barrier layer 29 provided on the recording layer 28, and the reference layer 30, on at least one magnetic stacked film 10, even when the MTJ elements are integrated as a magnetic memory device, such as an MRAM, incorrect writing and incorrect reading due to a stray magnetic field decrease as much as possible.

In the magnetic stacked film 10 and the magnetoresistive effect element 2 according to the second embodiment, the first ferromagnetic layer 12, the second ferromagnetic layer 16, the recording layer 28, and the reference layer 30 may employ any of in-plane magnetization and perpendicular magnetization. In the case of in-plane magnetization, the magnetization direction is not limited to be in a direction perpendicular to the direction of the current I and only needs to be in the x direction, the y direction, or further within the xy plane. That is, for example, a type Y in which the axis of easy magnetization and the spin are parallel/antiparallel or a type X and a type Z in which a direction of easy magnetization and the spin are perpendicular to one another may be employed.

### Third Embodiment

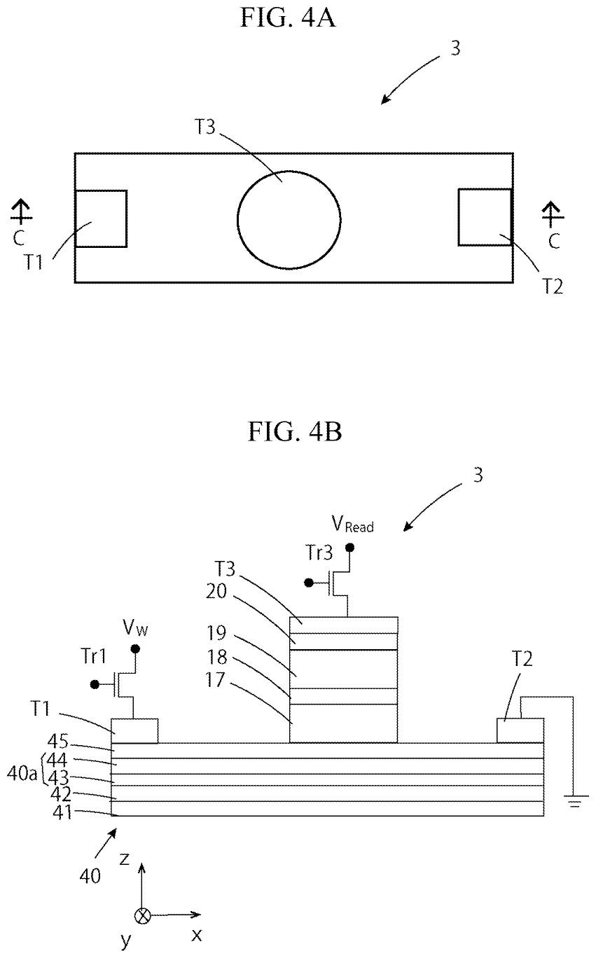

FIG. 4A is a plan view of a magnetic stacked film and a magnetoresistive effect element using the magnetic stacked film according to the third embodiment of the present invention. FIG. 4B is a sectional view taken along the line C-C. As illustrated in FIG. 4A and FIG. 4B, a magnetic stacked film 40 according to the third embodiment of the present invention includes an underlayer 41 provided on a substrate (not illustrated), a first ferromagnetic layer 42 provided on the underlayer 41, an interlayer coupling layer 43 provided on the first ferromagnetic layer 42, a first non-magnetic layer 44 provided on the interlayer coupling layer 43, and a second ferromagnetic layer 45 provided on the first non-magnetic layer 44. That is, the magnetic stacked film 40 is configured as follows. The interlayer coupling layer 43 and the first non-magnetic layer 44 are in contact with one another, the first ferromagnetic layer 42 is in contact with the lower surface of the interlayer coupling layer 43, the second ferromagnetic layer 45 is in contact with the upper surface of the first non-magnetic layer 44, the interlayer coupling layer 43 and the first non-magnetic layer 44 are interposed between the first ferromagnetic layer 42 and the second ferromagnetic layer 45, the first ferromagnetic layer 42 is provided in contact with the lower surface of the interlayer coupling layer 43, and the second ferromagnetic layer 45 is provided in contact with the upper surface of the first non-magnetic layer 44. That is, the magnetic stacked film 40 has a configuration of one layer of the non-magnetic layer, not two layers of the non-magnetic layers as in the magnetic stacked film 10 according to the first embodiment. In the illustrated example, on the second ferromagnetic layer 45, the recording layer 17 made of a material that allows magnetization reversal is formed. In the third embodiment, the interlayer coupling layer 43 and the first non-magnetic layer 44 constitute an antiferromagnetic coupling layer 40a. The interlayer coupling layer 43 may be referred to as an interlayer coupling non-magnetic layer. Note that the interlayer coupling layer 43 and the first non-magnetic layer 44 may be upside down. The first non-magnetic layer 44 may be simply referred to as the non-magnetic layer 44.

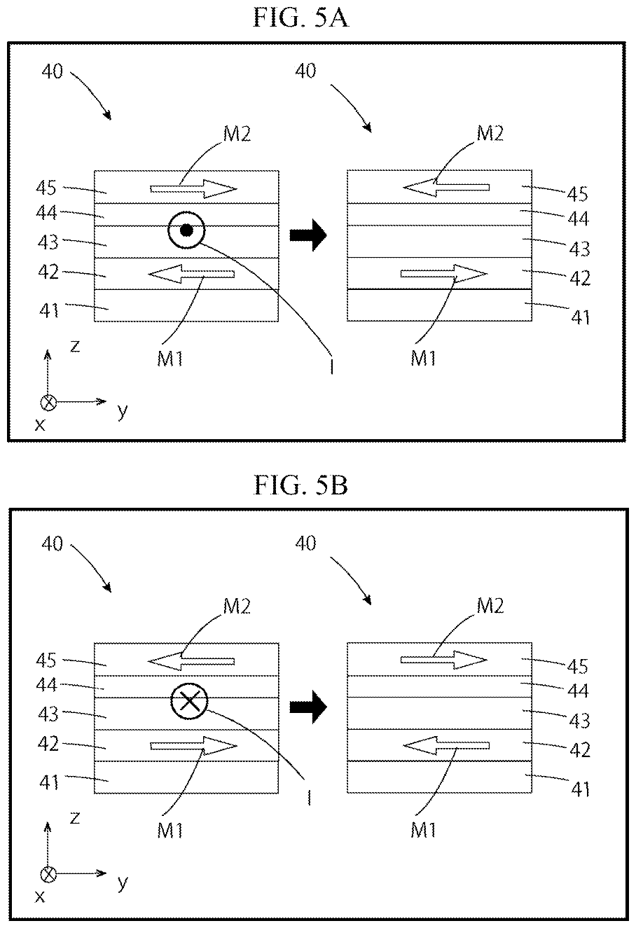

FIG. 5A is a diagram for describing a state in which current flows to the magnetic stacked film 40 according to the third embodiment of the present invention to write data “O” in the recording layer 17. As illustrated in FIG. 5A, before the current flows in the −x direction, magnetizations are in inverse directions from one another between the first ferromagnetic layer 42 and the second ferromagnetic layer 45. By flowing current to the magnetic stacked film 40 in the −x direction, a spin current (a flow of a spin motion) occurs by the spin Hall effect due to by the spin-orbit interaction. The respective spins in the inverse directions from one another flow in the corresponding directions in the ±z directions of the magnetic stacked film 40, by the spin currents flowing through the magnetic stacked film 40, the respective spin in one direction and spin in the other direction separately flow to the up and the down, and the spins are accumulated on an interface between the first ferromagnetic layer 42 and the interlayer coupling layer 43 and an interface between the first non-magnetic layer 44 and the second ferromagnetic layer 45 and are absorbed to the second ferromagnetic layer 45. Therefore, as illustrated in FIG. 5A, the magnetizations of the first ferromagnetic layer 12 and the second ferromagnetic layer 16 are in the inverse directions of the directions before the current flows in the −x direction. Thus, flowing the current to the magnetic stacked film 40 in the −x direction generates a spin-orbit torque caused by the current, and the respective magnetizations of the first ferromagnetic layer 42 and the second ferromagnetic layer 45 are switched.

Here, in the magnetic stacked film 40 according to the third embodiment of the present invention, since the second ferromagnetic layer 45 is in contact with the first non-magnetic layer 44 having a large spin Hall angle, a spin torque increases compared with a case of not providing the first non-magnetic layer 44, and magnetizations of the first ferromagnetic layer 42 and the second ferromagnetic layer 45 can be simultaneously switched.

Provisionally, in the magnetic stacked film 40, when the first non-magnetic layer 44 is not provided and the interlayer coupling layer 43 is directly interposed between the first ferromagnetic layer 42 and the second ferromagnetic layer 45, even when the interlayer coupling layer 43 is made of Ru or Ir and the antiferromagnetic coupling is achieved, since spin Hall angles of Ru and Ir are considerably small, achieving magnetization reversal by the spin Hall effect is considerably difficult.

FIG. 5B is a diagram for describing a state in which current flows to the magnetic stacked film 40 according to the third embodiment of the present invention in an inverse direction to write data “1” in the recording layer 17. As illustrated in FIG. 5B, before the current flows in the +x direction as the inverse direction, magnetizations are in inverse directions from one another between the first ferromagnetic layer 42 and the second ferromagnetic layer 45. By flowing current to the magnetic stacked film 40 in the +x direction, a spin current (a flow of a spin motion) occurs by the spin Hall effect by the spin-orbit interaction. The respective spins in the inverse directions from one another flow in the corresponding directions in the ±z directions (here, the inverse directions compared with the case of FIG. 5A) of the magnetic stacked film 40, by the spin currents flowing through the magnetic stacked film 40, the respective spin in one direction and spin in the other direction separately flow to the up and the down, the spins are accumulated on an interface between the first ferromagnetic layer 42 and the interlayer coupling layer 43 and an interface between the first non-magnetic layer 44 and the second ferromagnetic layer 45 and are absorbed by the first ferromagnetic layer 42 and the second ferromagnetic layer 45. Therefore, as illustrated in FIG. 5B, the respective magnetizations of the first ferromagnetic layer 42 and the second ferromagnetic layer 45 are in the inverse directions of the directions before the current flows in the +x direction. Thus, flowing the current to the magnetic stacked film 40 in the +x direction generates a spin-orbit torque caused by the current, and the respective magnetizations of the first ferromagnetic layer 42 and the second ferromagnetic layer 45 are switched.

Here, compared with the case where antiferromagnetic coupling is kept in the magnetic stacked film of the first ferromagnetic layer/the interlayer coupling layer/the second ferromagnetic layer, the antiferromagnetic coupling is also kept by configuring the magnetic stacked film 40 such that the interlayer coupling layer 43 and the first non-magnetic layer 44 are in contact with one another as in the third embodiment of the present invention. This will be described in Demonstrative Examples described later. Because it is considered that the antiferromagnetic coupling occurred by RKKY interaction by a spanning vector qs in a [111] direction of a Fermi surface of Ir has the same fcc structure also in Pt, and therefore a topological characteristic of the Fermi surface is nearly the same, and thus the RKKY interaction would be kept.

While FIG. 5A and FIG. 5B illustrate the case of in-plane magnetization, the same applies to a case of perpendicular magnetization. In the case of in-plane magnetization, the magnetization direction is not limited to be in a direction perpendicular to the direction of the current I and only needs to be the x direction, the y direction, and further within the xy plane. That is, for example, a type Y in which the axis of easy magnetization and the spin are parallel/antiparallel or a type X and a type Z in which a direction of easy magnetization and the spin are perpendicular to one another may be employed.

As one utilization aspect of the magnetic stacked film 40, the description will be continued with an example of a magnetoresistive effect element 3. In the third embodiment, the magnetic stacked film 40 has a surface of providing a reading antiferromagnetic layer as the recording layer 17 on the second ferromagnetic layer 45 and the recording layer 17 having reversible magnetization is provided. The reading bulk antiferromagnetic layer is preferably an Ir—Mn alloy, an Fe—Mn alloy, and the like. On the recording layer 17, the barrier layer (also referred to as the tunnel barrier layer) 18 is provided to be in contact with the recording layer 17. The tunnel barrier layer 18 is preferably made of an insulating material, such as MgO, Al₂O₃, AlN, and MgAlO. On the tunnel barrier layer 18, the non-magnetic layer 19 as the reference layer is provided. The non-magnetic layer 19 is not especially limited, but is preferably Pt, Cu, Al, and the like. Stacking the recording layer 17, the tunnel barrier layer 18, and the non-magnetic layer 19 constitutes the magnetoresistive effect element 3 using a tunneling anisotropic magnetoresistance (TAMR) effect. Here, the reading bulk antiferromagnetic layer as the recording layer 17 and the second ferromagnetic layer 45 are coupled by an exchange coupling action and the antiferromagnetic moment in the reading bulk antiferromagnetic layer rotates by magnetization reversal in the second ferromagnetic layer 45, and therefore the magnitude of the resistance differs significantly.

On either of the uppermost surface and the lowermost surface of the magnetic stacked film 40, the first terminal T1 and the second terminal T2 are provided, and the first terminal T1 and the second terminal T2 are separated in a direction perpendicular to the stacking direction of the magnetic stacked film 40. The write current flows between the first terminal T1 and the second terminal T2. On the non-magnetic layer 19, the cap layer 20 is provided and the third terminal T3 is provided, and a read current can be applied to the third terminal T3.

Next, the specific material of the magnetic stacked film 40 will be described. The interlayer coupling layer 43 is made of a metal or an alloy including at least any one of Ir, Rh, and Ru. When Ir is included, the thickness may be in a range from 0.4 nm or more and 0.7 nm or less. In the case of Ru, the thickness may be in a range from 0.6 nm or more and 0.9 nm or less. The interlayer coupling layer 43 is preferably made of a metal or an alloy having an fcc structure including at least any one of Ir and Rh. The interlayer coupling layer 43 is especially preferably made of a metal or an alloy having an fcc structure including any one of Ir, an Ir—Os alloy, Rh, an Ir—Rh alloy, an Ir—Re alloy, and an Ir—Ru alloy.

The first non-magnetic layer 44 is made of a metal or an alloy including Pt. The first non-magnetic layer 44 is preferably made of a metal or an alloy having an fcc structure including Pt. The first non-magnetic layer 44 is especially preferably selected from a metal and an alloy having an fcc structure of any of Pt, a Pt—Au alloy, a Pt—Ir alloy, a Pt—Cu alloy, and a Pt—Cr alloy. The first non-magnetic layer 44 may be a Pt—Pd alloy, a Pt—Hf alloy, and a Pt—Al alloy.

In the magnetic stacked film 40 according to the third embodiment of the present invention, the first non-magnetic layer 44 and the interlayer coupling layer 43 are provided to be in contact with one another, thus antiferromagnetically coupling the first ferromagnetic layer 42 and the second ferromagnetic layer 45. Therefore, a structure in which a stray magnetic field does not occur in the magnetic stacked film 40 itself is employed. Since the two layers of the ferromagnetic layers are present and they are antiferromagnetically coupled, the thermal stability constant Δ can be increased. Additionally, in the conventional SOT element, since the first ferromagnetic layer 42 has been absent at the lower portion, only a spin current accumulated on an interface between the second ferromagnetic layer 45 and the first non-magnetic layer 44 has been utilized for magnetization reversal. With the element structure, not only the spin current accumulated on the interface between the second ferromagnetic layer 45 and the first non-magnetic layer 44 generated when a current pulse flows, but also the spin current accumulated on the interface between the first ferromagnetic layer 42 and the interlayer coupling layer 43 can be utilized, and therefore reverse energy efficiency can be increased to the extent of double. With this structure, since the large spin Hall effect of the first non-magnetic layer 44 can be used, compared with a case of not providing the first non-magnetic layer 44, inversion current of the spin can be significantly reduced. For formation of further perfect antiferromagnetic coupling, the first ferromagnetic layer 42 and the second ferromagnetic layer 45 preferably have the same thickness.

The use of the magnetic stacked film 40 as a write control layer of the magnetoresistive effect element 3 using the SOT further improves write efficiency. The use of the magnetic stacked film 40 with such antiferromagnetic coupling improves a write speed faster.

In the magnetoresistive effect element 3 according to the third embodiment of the present invention, on the second ferromagnetic layer 45, the reading bulk antiferromagnetic layer as the recording layer 17 that couples by exchange interaction, the tunnel barrier layer 18 provided on the reading bulk antiferromagnetic layer, and the non-magnetic layer 19 are provided. The recording layer 17 couples by magnetization and exchange interaction of the second ferromagnetic layer 45. Accordingly, since the magnetoresistive effect element 3 itself is entirely constituted of the non-magnetic bodies, a stray magnetic field does not occur.

In view of this, by disposing a plurality of stacks on at least one magnetic stacked film 10, each stack including the reading bulk antiferromagnetic layer as the recording layer 17/the tunnel barrier layer 18/the fixed layer formed of the non-magnetic layer 19, even when the stacks are integrated as a magnetic memory device, such as an MRAM, incorrect writing and incorrect reading due to a stray magnetic field decreases as much as possible.

In the magnetic stacked film 40 and the magnetoresistive effect element 3 according to the third embodiment, the first ferromagnetic layer 42 and the second ferromagnetic layer 45 may be any of in-plane magnetization and perpendicular magnetization. In the case of in-plane magnetization, the magnetization direction is not limited to be in a direction perpendicular to the direction of the current I and only needs to be the x direction, the y direction, and further within the xy plane. That is, for example, a type Y in which the axis of easy magnetization and the spin are parallel/antiparallel or a type X and a type Z in which a direction of easy magnetization and the spin are perpendicular to one another may be employed.

### Fourth Embodiment

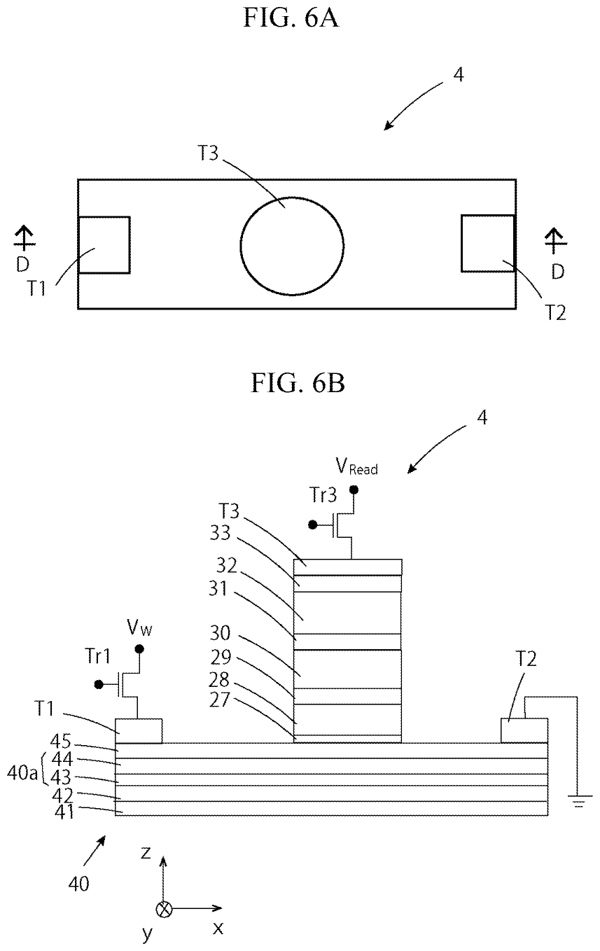

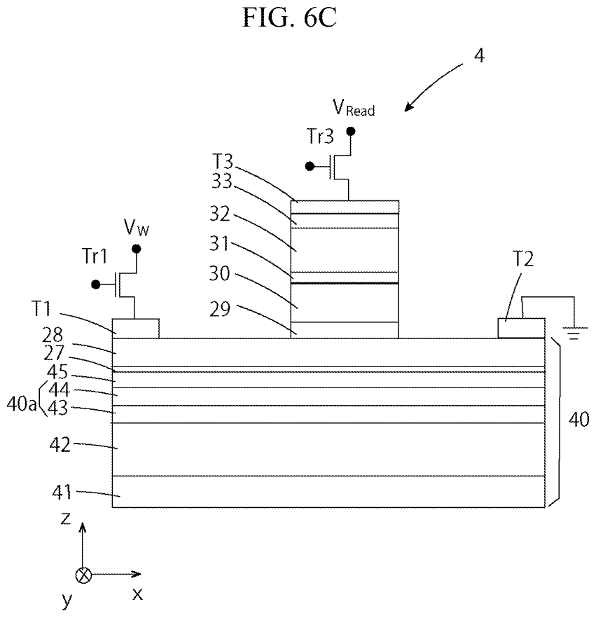

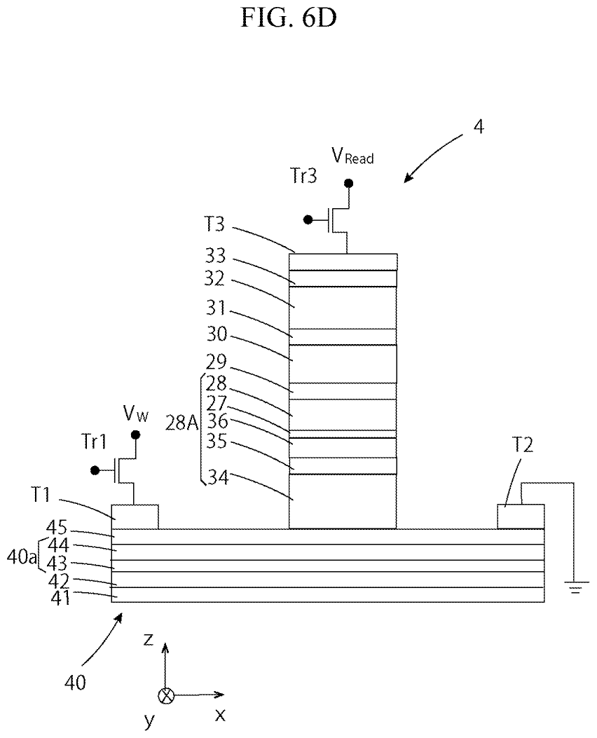

FIG. 6A is a plan view of a magnetic stacked film and a magnetoresistive effect element using the magnetic stacked film according to the fourth embodiment of the present invention. FIG. 6B is a sectional view taken along the line D-D. The magnetic stacked film 40 according to the fourth embodiment of the present invention has a configuration similar to that of the third embodiment. Accordingly, in the magnetic stacked film 40 according to the fourth embodiment of the present invention, the interlayer coupling layer 43 and the first non-magnetic layer 44 are provided to be in contact with one another, thus antiferromagnetically coupling the first ferromagnetic layer 42 and the second ferromagnetic layer 45. Therefore, a structure in which a stray magnetic field does not occur in the magnetic stacked film 40 itself is employed. Accordingly, thermal stability is satisfactory. For formation of further perfect antiferromagnetic coupling, the first ferromagnetic layer 42 and the second ferromagnetic layer 45 preferably have the same thickness. The use of the magnetic stacked film 40 as a write control layer of a magnetoresistive effect element 4 using the SOT further improves write efficiency. The use of the magnetic stacked film 40 with such antiferromagnetic coupling improves a write speed faster. The detailed description is similar to the third embodiment and therefore is omitted.

In the fourth embodiment, in addition to the non-magnetic layer 27, the recording layer 28, the tunnel barrier layer 29, the reference layer 30, the non-magnetic layer 31, the anchoring layer 32, the cap layer 33, and the third terminal T3 provided on the magnetic stacked film 40, the first terminal T1, the second terminal T2, the third terminal T3, and the respective transistors Tr1, Tr1, and Tr3 have the configurations similar to those of the second embodiment, and thus has the similar effects as the second embodiment. On the second ferromagnetic layer 45, what is called an MTJ element including the ferromagnetic layer as the recording layer 28 coupled by exchange interaction, the tunnel barrier layer 29 provided on the recording layer 28, and the reference layer 30 is configured. Since the recording layer 28 couples by magnetization and exchange interaction of the second ferromagnetic layer 45, the structure allows avoiding a stray magnetic field. FIG. 6C is a sectional view in a different viewpoint of the magnetic stacked film 40 and the magnetoresistive effect element 4 according to the fourth embodiment of the present invention. As illustrated in FIG. 6C, as a structure of further decreasing a stray magnetic field, it is preferable that the layers up to the recording layer 28 are configured as the magnetic stacked film 40 and values of the magnetization of the first ferromagnetic layer 42 and the magnetization of the second ferromagnetic layer 45/the non-magnetic layer 27/the recording layer 28 are canceled. FIG. 6D is a different sectional view of the magnetic stacked film 40 and the magnetoresistive effect element 4 according to the fourth embodiment of the present invention. As illustrated in FIG. 6D, the entire Co layer 34/Ir layer 35/Co layer 36/non-magnetic layer 27/recording layer 28 with the recording layer structure being the antiferromagnetic coupling structure may be configured as the recording layer 28A. The Co layers 34 and 36 are not limited to the ferromagnetic layer other than Co or the Ir layer 35 but may be, for example, an Ru layer made of a material of the interlayer coupling layer. Adjusting the thicknesses of the films constituting the reference layer 30 and the anchoring layer 32 allows avoiding a stray magnetic field. Accordingly, the magnetoresistive effect element 4 itself does not cause a stray magnetic field. In view of this, by disposing a plurality of what is called MTJ elements, each element including the ferromagnetic layer as the recording layer 28, the tunnel barrier layer 29 provided on the recording layer 28, and the reference layer 30, on at least one magnetic stacked film 40, even when the MTJ elements are integrated as a magnetic memory device, such as an MRAM, incorrect writing and incorrect reading due to a stray magnetic field decreases as much as possible. The detailed description is similar to the second embodiment and therefore is omitted. In the magnetic stacked film 40 and the magnetoresistive effect element 4 according to the fourth embodiment, the first ferromagnetic layer 42, the second ferromagnetic layer 45, the recording layer 28, and the reference layer 30 may be any of in-plane magnetization and perpendicular magnetization. In the case of in-plane magnetization, the magnetization direction is not limited to be in a direction perpendicular to the direction of the current I, and only needs to be the x direction, the y direction, and further within the xy plane. That is, for example, a type Y in which the axis of easy magnetization and the spin are parallel/antiparallel or a type X and a type Z in which a direction of easy magnetization and the spin are perpendicular to one another may be employed.

### Other Embodiments

The magnetic stacked films 10 and 40 according to the embodiments of the present invention are not used simply only for the magnetoresistive effect elements 1, 2, 3, and 4 using the SOT, but also can be used as a material and a configuration in which a leakage of a stray magnetic field does not occur by antiferromagnetic coupling in various elements, such as a spintronics element, and devices.

### Demonstrative Examples

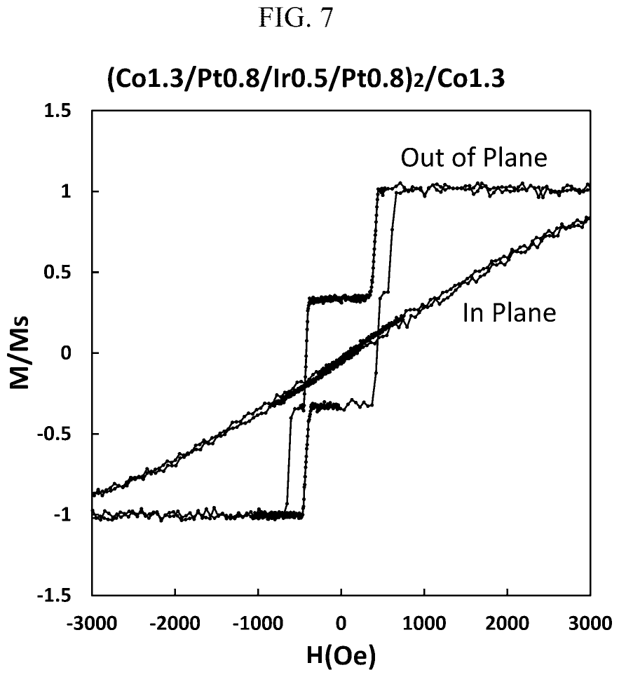

As Demonstrative Example 1, (Co1.3/Pt0.8/Ir0.5/Pt0.8)₂/Co1.3 was formed on an underlayer, an external magnetic field was changed, and magnetization was measured. Here, numerals after the element symbols mean thicknesses in nm unit of layers formed of the element symbols and, for example, Co1.3 means a Co layer at 1.3 nm. FIG. 7 is magnetization curves of a sample of Demonstrative Example 1. The horizontal axis indicates an external magnetic field H (Oe) and the vertical axis indicates M/Ms. One magnetization curve indicates a case where a perpendicular magnetic field was applied as the external magnetic field, and the other magnetization curve indicates a case where an in-plane magnetic field was applied as the external magnetic field. It has been found that when the perpendicular magnetic field is applied, antiferromagnetic coupling occurs in a zero magnetic field.

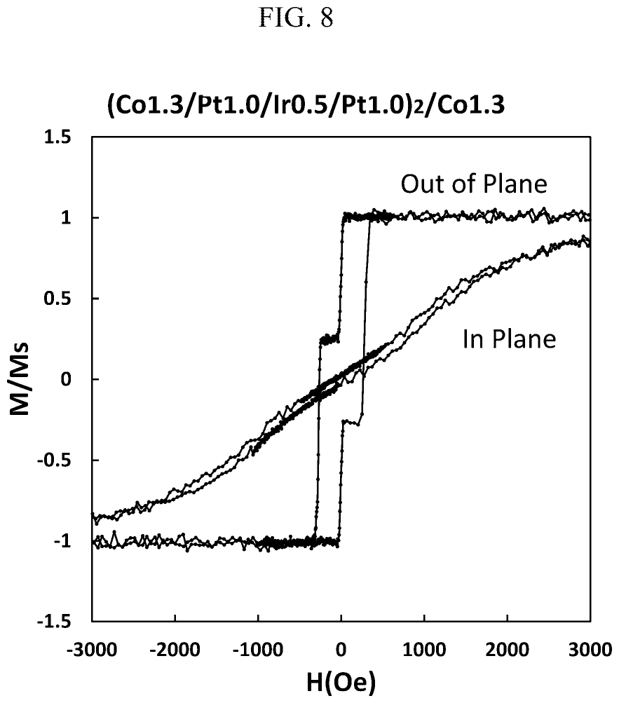

As Demonstrative Example 2, (Co1.3/Pt1.0/Ir0.5/Pt1.0)₂/Co1.3 was formed on an underlayer, an external magnetic field was changed, and magnetization was measured. FIG. 8 is magnetization curves of a sample of Demonstrative Example 2. The horizontal axis indicates an external magnetic field H (Oe) and the vertical axis indicates magnetization M/Ms. One magnetization curve indicates a case where a perpendicular magnetic field was applied as the external magnetic field, and the other magnetization curve indicates a case where an in-plane magnetic field was applied as the external magnetic field. It has been found that when the perpendicular magnetic field is applied, antiferromagnetic coupling occurs in a zero magnetic field.

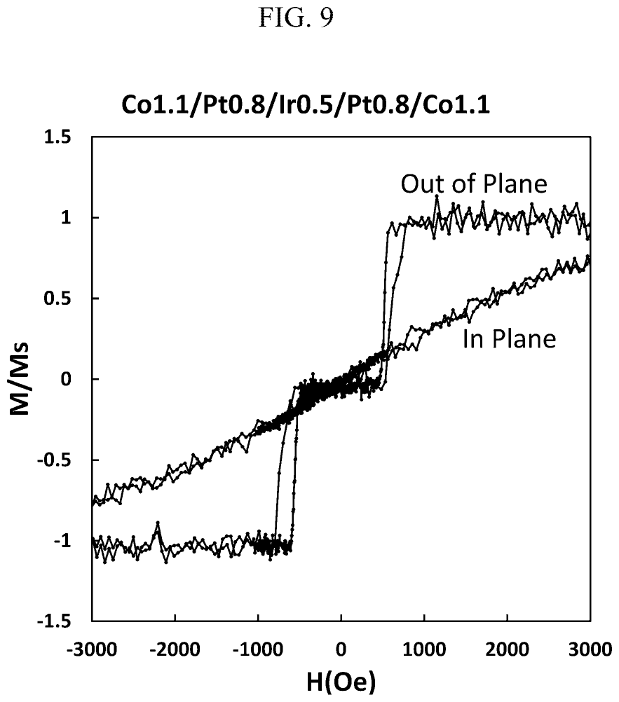

As Demonstrative Example 3, Co1.1/Pt0.8/Ir0.5/Pt0.8/Co1.1 was formed on an underlayer, an external magnetic field was changed, and magnetization was measured. FIG. 9 is magnetization curves of a sample of Demonstrative Example 3. The horizontal axis indicates an external magnetic field H (Oe) and the vertical axis indicates M/Ms. One magnetization curve indicates a case where a perpendicular magnetic field was applied as the external magnetic field, and the other magnetization curve indicates a case where an in-plane magnetic field was applied as the external magnetic field. It has been found that when the perpendicular magnetic field is applied, antiferromagnetic coupling occurs.

Thus, it has been found that when the antiferromagnetic coupling layer formed of the Pt layer, the Ir layer, and the Pt layer was interposed between the upper and lower Co layers, magnetization of one Co layer is in an inverse direction to the magnetization direction of the other Co layer.

Therefore, as Demonstrative Example 4, a Pt layer was inserted into the Co layer/the Ir layer/the Co layer to examine how antiferromagnetic coupling of Ir is changed. A thickness t_Ir of the Ir layer was set to 0.5 nm, 0.55 nm, or 1.4 nm, and the sum of the thicknesses of the Pt layer and the Ir layer, that is, the total film thickness of the non-magnetic layers was adjusted to be in a range from 0.5 to 2.5 nm. There are cases where non-magnetic layers are Ir/Pt, Pt/Ir/Pt, and only Ir layers. The case of only the Ir layers was Comparative Example. Additionally, when the Pt layers were provided above and below the Ir layer, the thicknesses of the upper and lower Pt layers were set to be the same.

In each sample, an interlayer exchange coupling Jₑₓ (mJ/m²) was measured. Table 1 summarizes the results.

TABLE 1

| | Non-magnetic | | | |
|---|---|---|---|---|
| | structure | t_Ir (nm) | t_total (nm) | Jex(mJ/m²) |
| Sample 1 | Ir/Pt | 0.5 | 1.5 | 0.821 |
| Sample 2 | Ir/Pt | 0.6 | 1.6 | 0.415 |
| Sample 3 | Pt/Ir/Pt | 0.5 | 1.7 | 0.561 |
| Sample 4 | Pt/Ir/Pt | 0.5 | 2.5 | 0.0487 |
| Sample 5 | Ir/Pt | 0.5 | 1.5 | 0.218 |
| Sample 6 | Pt/Ir/Pt | 0.5 | 2.1 | 0.224 |
| Sample 7 | Pt/Ir/Pt | 0.5 | 2.1 | 0.188 |
| Sample 8 | Pt/Ir/Pt | 0.5 | 1.6 | 0.271 |
| Sample 9 | Pt/Ir/Pt | 0.5 | 2.1 | 0.0881 |
| Sample 10 | Ir | 0.5 | 0.5 | 2.12 |
| Sample 11 | Ir | 1.4 | 1.4 | 0.398 |
| Sample 12 | Ir/Pt | 0.5 | 1.1 | 0.9295 |
| Sample 13 | Ir/Pt | 0.55 | 1.15 | 0.971 |
| Sample 14 | Ir/Pt | 1.4 | 2 | 0.0862 |
| Sample 15 | Ir/Pt | 1.5 | 2.1 | 0.0635 |

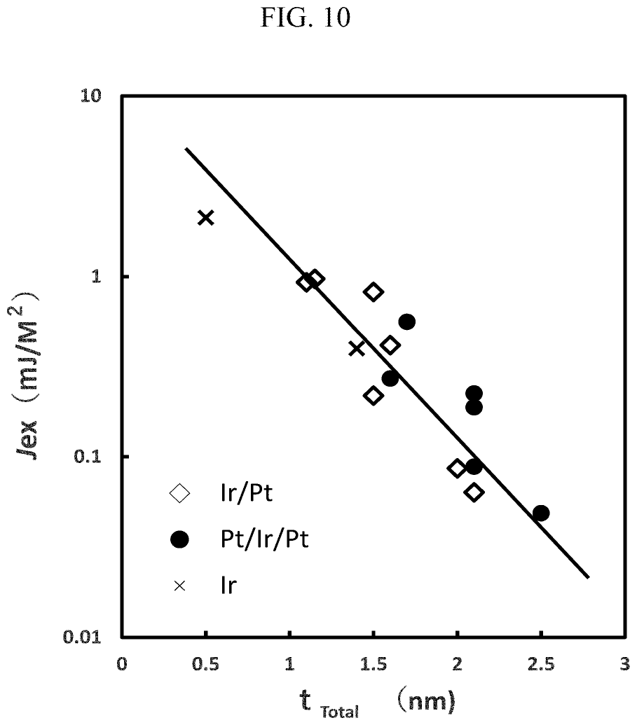

FIG. 10 is a graph illustrating the dependence of the interlayer exchange coupling Jₑₓ (mJ/m²) on the total film thickness tₜₒₜₐₗ (nm) of non-magnetic layers. It has been found from FIG. 10 that the insertion of the Pt layer into the stack of Co/Ir/Co monotonically reduces the interlayer exchange coupling Jₑₓ, which indicates the magnitude of the antiferromagnetic coupling of Ir, in association with thickening the non-magnetic layer. Moreover, it has been confirmed that even when the total film thickness of Pt/Ir/Pt is 2.5 nm, antiferromagnetic coupling occurs and it has been apparent that the total film thickness of Pt/Ir/Pt is from 1.5 to 2.5 nm, thus ensuring fabricating the antiferromagnetic coupling films continuously in the wide range. This indicates that while RKKY interaction propagates in Pt, RKKY oscillation does not occur.

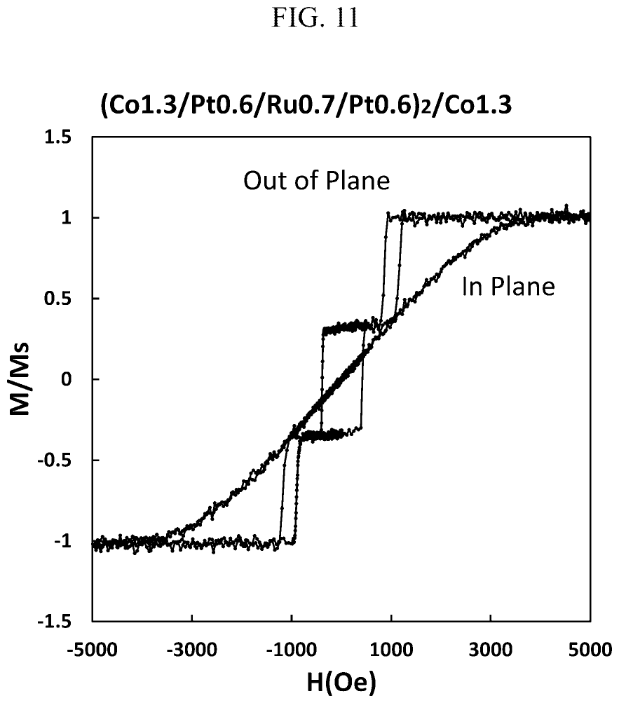

As Demonstrative Example 5, (Co1.3/Pt0.6/Ru0.7/Pt0.6)₂/Co1.3 was formed on an underlayer, an external magnetic field was changed, and magnetization was measured. FIG. 11 is magnetization curves of a sample of Demonstrative Example 5. The horizontal axis indicates an external magnetic field H (Oe) and the vertical axis indicates M/Ms. Ms is saturation magnetization. One magnetization curve indicates a case where a perpendicular magnetic field was applied as the external magnetic field, and the other magnetization curve indicates a case where an in-plane magnetic field was applied as the external magnetic field. It has been found that when the perpendicular magnetic field is applied, antiferromagnetic coupling occurs in a zero magnetic field.

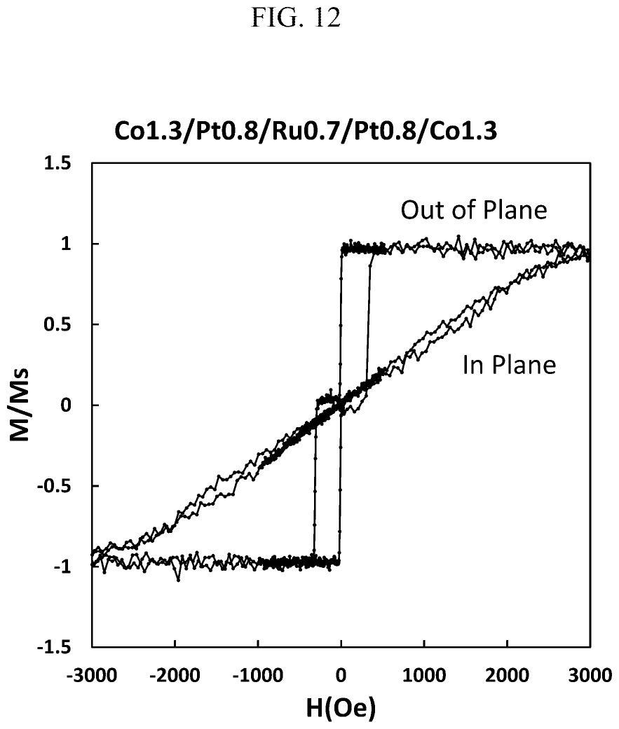

As Demonstrative Example 6, (Co1.3/Pt0.8/Ru0.7/Pt0.8)₂/Co1.3 was formed on an underlayer, an external magnetic field was changed, and magnetization was measured. FIG. 12 is magnetization curves of a sample of Demonstrative Example 6. The horizontal axis indicates an external magnetic field H (Oe) and the vertical axis indicates M/Ms. Ms is saturation magnetization. One magnetization curve indicates a case where a perpendicular magnetic field was applied as the external magnetic field, and the other magnetization curve indicates a case where an in-plane magnetic field was applied as the external magnetic field. It has been found that when the perpendicular magnetic field is applied, antiferromagnetic coupling occurs in a zero magnetic field.

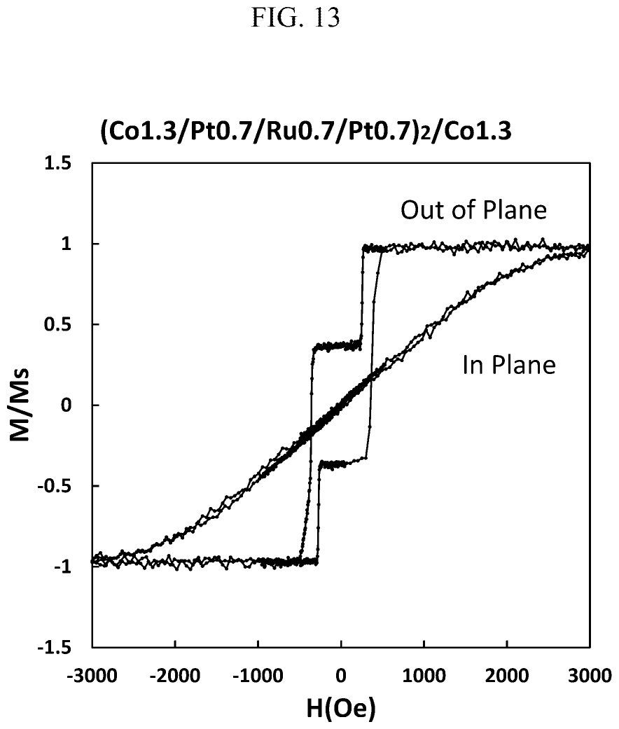

As Demonstrative Example 7, (Co1.3/Pt0.7/Ru0.7/Pt0.7)₂/Co1.3 was formed on an underlayer, an external magnetic field was changed, and magnetization was measured. FIG. 13 is magnetization curves of a sample of Demonstrative Example 7. The horizontal axis indicates an external magnetic field H (Oe) and the vertical axis indicates M/Ms. Ms is saturation magnetization. One magnetization curve indicates a case where a perpendicular magnetic field was applied as the external magnetic field, and the other magnetization curve indicates a case where an in-plane magnetic field was applied as the external magnetic field. It has been found that when the perpendicular magnetic field is applied, antiferromagnetic coupling occurs in a zero magnetic field.

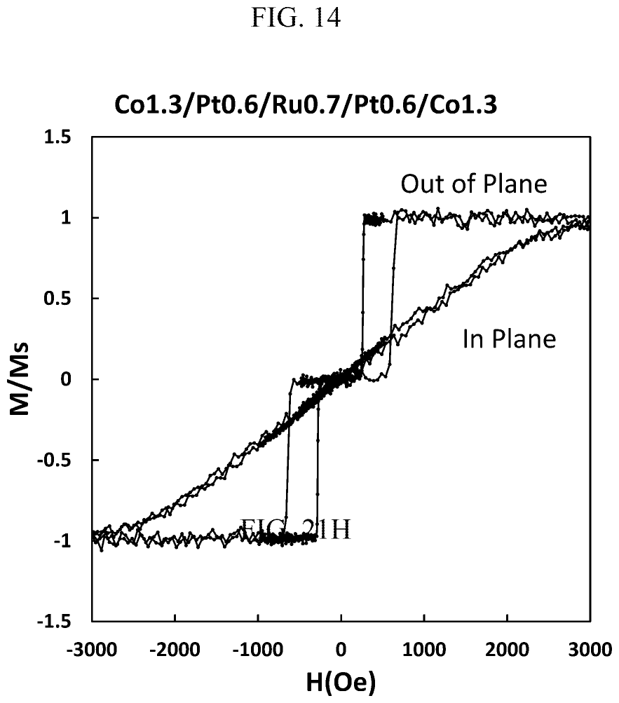

As Demonstrative Example 8, Co1.3/Pt0.6/Ru0.7/Pt0.6/Co1.3 was formed on an underlayer, an external magnetic field was changed, and magnetization was measured. FIG. 14 is magnetization curves of a sample of Demonstrative Example 8. The horizontal axis indicates an external magnetic field H (Oe) and the vertical axis indicates M/Ms. Ms is saturation magnetization. One magnetization curve indicates a case where a perpendicular magnetic field was applied as the external magnetic field, and the other magnetization curve indicates a case where an in-plane magnetic field was applied as the external magnetic field. It has been found that when the perpendicular magnetic field is applied, antiferromagnetic coupling occurs in a zero magnetic field.

Thus, it has been found that when the antiferromagnetic coupling layer formed of the Pt layer, the Ru layer, and the Pt layer was interposed between the upper and lower Co layers, magnetization of one Co layer is in an inverse direction to the magnetization direction of the other Co layer.

Therefore, as Demonstrative Example 9, a Pt layer was inserted into the Co layer/the Ru layer/the Co layer to examine how antiferromagnetic coupling of Ru is changed. A thickness t_Ru of the Ru layer was set to 0.4 nm, 0.7 nm, or 0.8 nm, and the sum of the thicknesses of the Pt layer and the Ru layer, that is, the total film thickness of the non-magnetic layers was adjusted to be in a range from 0.4 to 2.3 nm. There are cases where non-magnetic layers are Ru/Pt, Pt/Ru/Pt, and only Ru layers. The case of only the Ru layers was Comparative Example. Additionally, when the Pt layers were provided on upper and lower parts of the Ru layer, the thicknesses of the upper and lower Pt layers were set to be the same.

In each sample, an interlayer exchange coupling Jₑₓ (mJ/m²) was measured. Table 1 summarizes the results.

TABLE 2

| | Non-magnetic | | | |
|---|---|---|---|---|
| | structure | t_Ru (nm) | t_total (nm) | Jex(mJ/m²) |
| Sample 16 | Ru/Pt | 0.7 | 1.7 | 0.28 |
| Sample 17 | Pt/Ru/Pt | 0.7 | 1.9 | 0.206 |
| Sample 18 | Ru/Pt | 0.7 | 1.7 | 0.119 |
| Sample 19 | Pt/Ru/Pt | 0.7 | 2.3 | 0.0408 |
| Sample 20 | Pt/Ru/Pt | 0.7 | 2.3 | 0.0273 |
| Sample 21 | Ru/Pt | 0.7 | 1.7 | 0.102 |
| Sample 22 | Ru/Pt | 0.7 | 1 | 1.06 |
| Sample 23 | Ru/Pt | 0.7 | 1.3 | 0.768 |
| Sample 24 | Pt/Ru/Pt | 0.7 | 2.1 | 0.0744 |
| Sample 25 | Pt/Ru/Pt | 0.7 | 1.9 | 0.093 |
| Sample 26 | Ru/Pt | 0.8 | 1.4 | 0.605 |
| Sample 27 | Ru | 0.4 | 0.4 | 2.28 |
| Sample 28 | Ru | 0.8 | 0.8 | 1.0264 |

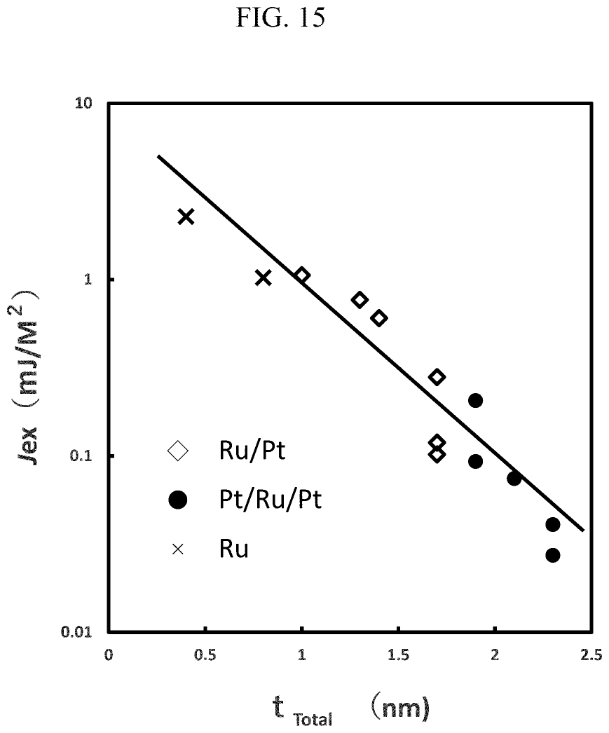

FIG. 15 is a graph illustrating the dependence of the interlayer exchange coupling Jₑₓ (mJ/m²) on total film thickness tₜₒₜₐₗ (nm) of non-magnetic layers. It has been found from FIG. 15 that the insertion of the Pt layer into the stack of Co/Ru/Co monotonically reduces the interlayer exchange coupling Jₑₓ, which indicates the magnitude of the antiferromagnetic coupling of Ru, in association with thickening the non-magnetic layer. Moreover, it has been confirmed that even when the total film thickness of Pt/Ru/Pt is 2.3 nm, antiferromagnetic coupling occurs. It has been apparent that the total film thickness of Pt/Ir/Pt is from 1.3 to 2.3 nm, thus ensuring fabricating the antiferromagnetic coupling films continuously in the wide range. This indicates that while RKKY interaction propagates in Pt, RKKY oscillation does not occur.

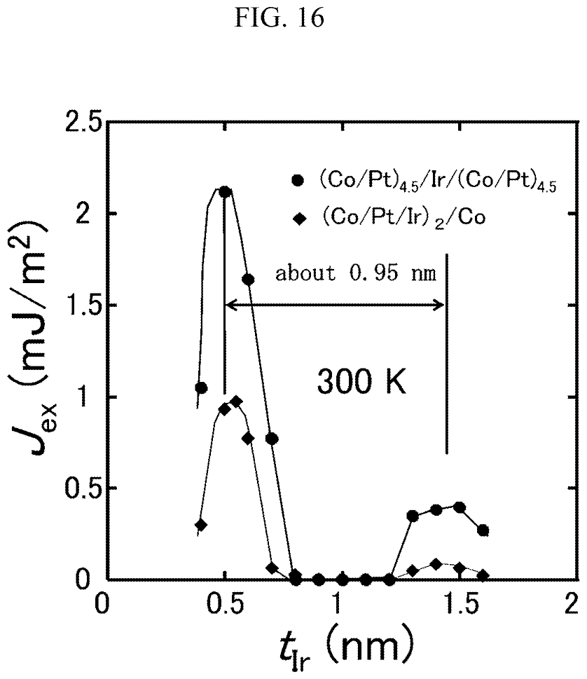

FIG. 16 is the dependence of the interlayer exchange coupling Jₑₓ on the Ir thickness. The horizontal axis indicates the thickness (nm) of Ir and the vertical axis indicates the magnitude of interlayer exchange coupling Jₑₓ. The black circle plots relate to (Co/Pt) 4.5/Ir/(Co/Pt) 45 and the diamond plots relate to (Co/Pt/Ir)₂/Co. Thicknesses t_{Ir} of the Ir layers of the respective plots are in increments of 0.1 nm like 0.4 nm, 0.5 nm, 0.6 nm, 0.7 nm, 0.8 nm, 0.9 nm, 1.0 nm, 1.1 nm, 1.2 nm, 1.3 nm, 1.4 nm, 1.5 nm, and 1.6 nm, and only the diamond plots include 0.55 nm. It has been found that even when the Pt layer as the non-magnetic layer is inserted between the interlayer coupling layer and the ferromagnetic layer, the interlayer exchange coupling Jₑₓ keeps the antiferromagnetic coupling. It is considered that this occurred since Ir and Pt had the same fcc structure, and thus the topological characteristics of the Fermi surfaces were nearly the same and RKKY interaction would propagate. Additionally, an antiferromagnetic oscillation period is nearly the same and the shift of a position is not observed, and therefore it has been apparent that oscillation in association with RKKY interaction does not occur in Pt. As described above, this is a cause that the antiferromagnetic coupling was observed in the wide range of the total thickness of Pt/Ir/Pt of from 1.5 nm to 2.5 nm. It has been apparent that since the large spin Hall angle of Pt can be used up to the Pt thickness of 1.0 nm, which is the thick film thickness, reversal efficiency of a spin can be significantly improved. It has been found that the thickness of the Ir layer is preferably in the range from 0.4 nm or more and 0.7 nm or less, and 1.3 nm or more and 1.6 nm or less.

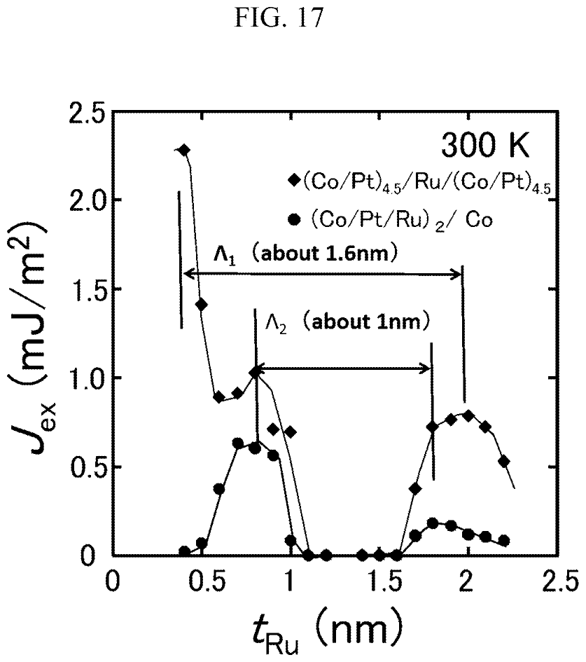

FIG. 17 is the dependence of the interlayer exchange coupling Jₑₓ on the Ru thickness. The horizontal axis indicates the thickness (nm) of Ru and the vertical axis indicates the magnitude of interlayer exchange coupling Jₑₓ. The black circle plots relate to (Co/Pt/Ru)₂/Co and the diamond plots relate to (Co/Pt)_{4.5}/Ru/(Co/Pt)_{4.5}. Thicknesses t_{Ru} of the Ru layers of the respective plots are 0.4 nm, 0.5 nm, 0.6 nm, 0.7 nm, 0.8 nm, 0.9 nm, 1.0 nm, 1.1 nm, 1.2 nm, 1.4 nm, 1.5 nm, 1.6 nm, 1.7 nm, 1.8 nm, 1.9 nm, 2.0 nm, 2.1 nm, and 2.2 nm. It has been found that when Pt is interposed, an interlayer exchange oscillation period A caused by interaction between the Ru layers disappears. It has been found that, as the thickness of Ru, a thickness at which the interlayer exchange coupling Jₑₓ has the 2nd peak only needs to be selected. It has been found that the thickness of the Ru layer is preferably in the range from 0.6 nm or more and 0.9 nm or less, and 1.7 nm or more and 2.2 nm or less.

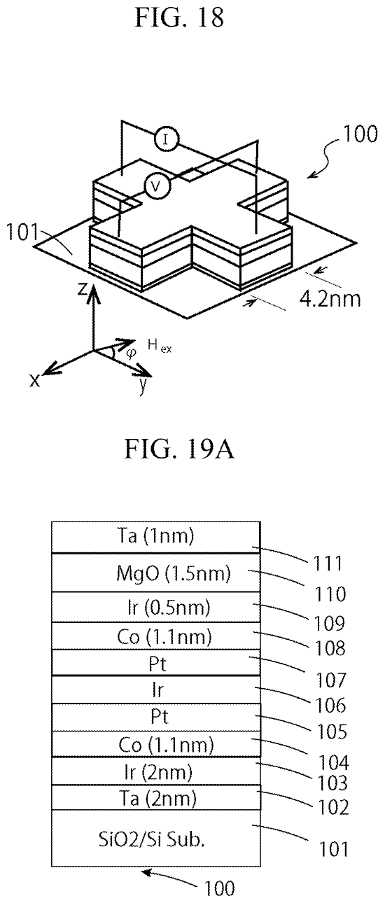

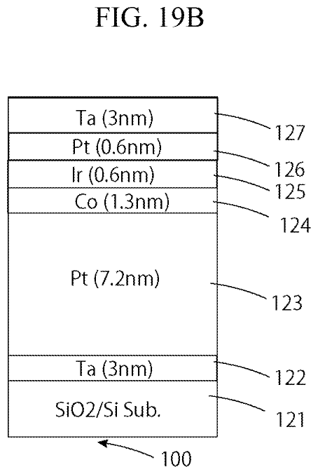

FIG. 18 is a diagram schematically illustrating a Hall bar and a measurement system that were fabricated as Sample 29. FIG. 19A is a sectional view of the fabricated Sample 29. As illustrated in FIG. 19A, Sample 29 included: an Si substrate 101 with a thermal oxide film; a Ta layer 102 with a thickness of 2.0 nm provided on the thermal oxide film; an Ir layer 103 with a thickness of 2.0 nm provided on the Ta layer 102; a Co layer 104 with a thickness of 1.1 nm provided on the Ir layer 103; a Pt layer 105 with a thickness of 0.8 nm provided on the Co layer 104; an Ir layer 106 with a thickness of 0.5 nm provided on the Pt layer 105; a Pt layer 107 with a thickness of 0.8 nm provided on the Ir layer 106; a Co layer 108 with a thickness of 1.1 nm provided on the Pt layer 107; an Ir layer 109 with a thickness of 0.5 nm provided on the Co layer 108; an MgO layer 110 with a thickness of 1.5 nm provided on the Ir layer 109; and a Ta layer 111 with a thickness of 1.0 nm provided on the MgO layer 110.

FIG. 19B is a sectional view of a fabricated sample of Comparative Example 2. As illustrated in FIG. 19B, the other comparison sample included: an Si substrate 121 with a thermal oxide film; a Ta layer 122 with a thickness of 3.0 nm provided on the thermal oxide film; a Pt layer 123 with a thickness of 7.2 nm provided on the Ta layer 122; a Co layer 124 with a thickness of 1.3 nm provided on the Pt layer 123; an Ir layer 125 with a thickness of 0.6 nm provided on the Co layer 124: a Pt layer 126 with a thickness of 0.6 nm provided on the Ir layer 125; and a Ta layer 127 with a thickness of 3.0 nm provided on the Pt layer 126.

The samples of Sample 29 and Comparative Example 2 were processed into a Hall bar, as illustrated in FIG. 18, by photolithography and Ar ion milling. The pulse current I was applied in the y direction to measure a Hall voltage V and a pulse current I dependence of Hall resistivity Rxy (Ω), where Rxy (Ω)=V/I.

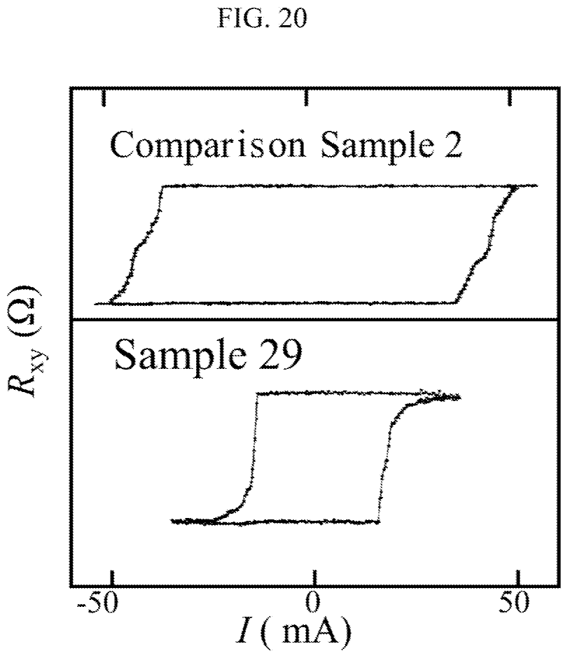

FIG. 20 is a result plotting the dependence of the Hall resistivity Rxy (Ω) on the pulse current in samples of Sample 29 and Comparative Example 2. The horizontal axis indicates the pulse current I (mA) and the vertical axis indicates the Hall resistivity Rxy (Ω). The results were observed when applying the pulse current I=200 μsec and a constant external magnetic field Hex of −26 mT in the direction of the pulse current I (φ=0 degree direction in FIG. 18) during measurement. What observed was an increase of the Hall resistivity Rxy at a certain current value when applying a pulse current in the + direction and a decrease of the Hall resistivity Rxy at a certain current value when applying a pulse current in the − direction, and thus, it has been found that a magnetic moment of the Co layer 104 is magnetically switched by the pulse current.

Observing absolute values of inversion currents of Sample 29 and the comparison sample, it has been found that a write current (inversion current) when the antiferromagnetic coupling film of Co/Pt/Ir/Pt/Co is used is reduced to the half of a write current (inversion current) when only the Pt layers are used. Accordingly, it has been found that energy during the writing also decreases to about a quarter.

As Sample 30 to Sample 34, the Hall bars similar to FIG. 18 and FIG. 19A were fabricated and measurement systems were established. As illustrated in FIG. 19A, Sample 30 to Sample 34 included: the Si substrate 101 with the thermal oxide film; the Ta layer 102 with a thickness of 2.0 nm provided on the thermal oxide film; the Ir layer 103 with a thickness of 2.0 nm provided on the Ta layer 102; the Co layer 104 with a thickness of 1.1 nm provided on the Ir layer 103; the Pt layer 105 with a thickness of 0.6 nm provided on the Co layer 104; the Ir layer 106 with a predetermined thickness provided on the Pt layer 105; the Pt layer 107 with a thickness of 0.6 nm provided on the Ir layer 106; the Co layer 108 with a thickness of 1.1 nm provided on the Pt layer 107; the Ir layer 109 with a thickness of 0.5 nm provided on the Co layer 108; the MgO layer 110 with a thickness of 1.5 nm provided on the Ir layer 109; and the Ta layer 111 with a thickness of 1.0 nm provided on the MgO layer 110. The thickness of the Ir layer 106 was 0.5 nm in [9] Sample 30, 0.52 nm in Sample 31, 0.56 nm in Sample 32, 0.58 nm in Sample 33, and 0.6 nm in Sample 34.

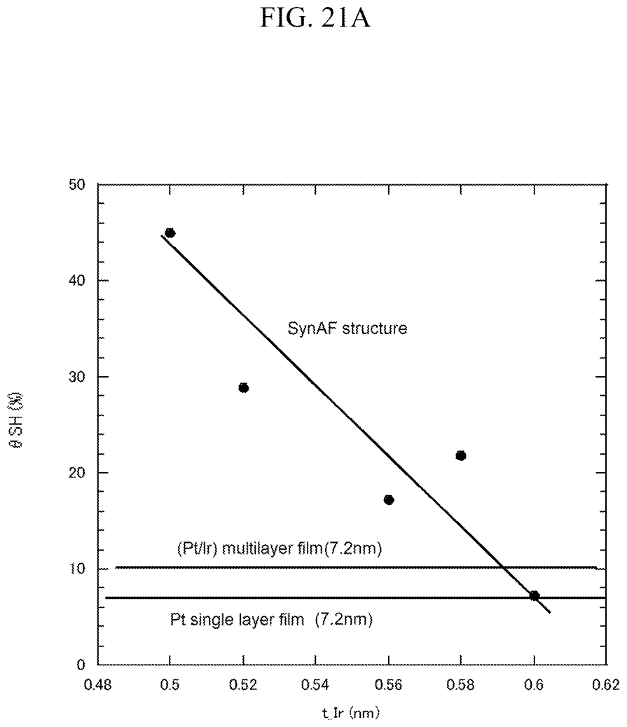

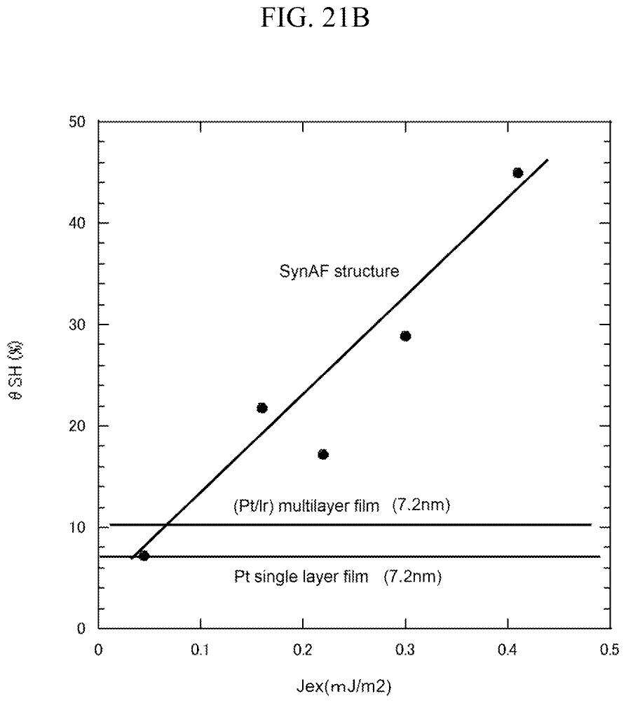

FIG. 21A is a result plotting the dependence of the orbit torque efficiency on the Ir layer thickness regarding Sample 30 to Sample 34. FIG. 21B is a result plotting the dependence of the spin-orbit torque efficiency on the interlayer exchange coupling Jₑₓ (mJ/m²) regarding Sample 30 to Sample 34. The horizontal axis of FIG. 21A indicates the Ir thickness t_Ir (nm), the horizontal axis of FIG. 21B indicates the interlayer exchange coupling Jₑₓ (mJ/m²), and the vertical axes of FIG. 21A and FIG. 21B indicate the spin-orbit torque efficiency θ_{SH} (%). FIG. 21A and FIG. 21B also illustrate results of cases of a multilayer film of (Pt 1.0 nm/Ir 0.8 nm)₄ and a Pt layer with a thickness of 7.2 nm as Comparative Examples instead of the Pt layer 105/the Ir layer 106/the Pt layer 107. A decrease in the thickness of the Ir layer from 0.6 nm to 0.5 nm increases the spin-orbit torque efficiency θ_{SH} (%). It has been apparent that since θ_{SH} (%) is in inverse proportion to the write current (inversion current) and power consumption, the use of the maximum value of Jₑₓ (mJ/m²) obtained in this time allows reducing the inversion current to about ⅕ and the power consumption to about 1/25 compared with those of the Pt/Co sample (Comparison Sample 2) in FIG. 20. It has been found from this result that the larger the interlayer exchange coupling Jₑₓ (mJ/m²) is, the more the power consumption can be reduced.

It has been found that, with the use of the Ir layer as the interlayer coupling layer, the larger the interlayer exchange coupling Jₑₓ (mJ/m²) is in the above range of Ir layer thickness, the larger the spin-orbit torque efficiency (spin Hall angle) is. Compared with the multilayer film of (Pt 1.0 nm/Ir 0.8 nm)₄ and the Pt layer with the thickness of 7.2 nm as comparative examples, in a Synthetic AF structure, the thickness of the Ir layer is preferably 0.4 nm or more and 0.6 nm or less, and more preferably 0.50 nm or more and 0.58 nm or less.

As Sample 35 to Sample 39, the Hall bars similar to FIG. 18 and FIG. 19A were fabricated and measurement systems were established. As illustrated in FIG. 19A, Sample 35 to Sample 39 included: the Si substrate 101 with the thermal oxide film; the Ta layer 102 with a thickness of 2.0 nm provided on the thermal oxide film; the Ir layer 103 with a thickness of 2.0 nm provided on the Ta layer 102; the Co layer 104 with a thickness of 1.1 nm provided on the Ir layer 103; the Pt layer 105 with a predetermined thickness provided on the Co layer 104; the Ir layer 106 with a thickness of 0.5 nm provided on the Pt layer 105; the Pt layer 107 with a predetermined thickness provided on the Ir layer 106; the Co layer 108 with a thickness of 1.1 nm provided on the Pt layer 107; the Ir layer 109 with a thickness of 0.5 nm provided on the Co layer 108; the MgO layer 110 with a thickness of 1.5 nm provided on the Ir layer 109; and the Ta layer 111 with a thickness of 1.0 nm provided on the MgO layer 110. The thicknesses of the Pt layer 105 and the Pt layer 107 were 0.8 nm in Sample 35, 0.7 nm in Sample 36, 0.6 nm in Sample 37, 0.5 nm in Sample 38, and 0.4 nm in Sample 39.

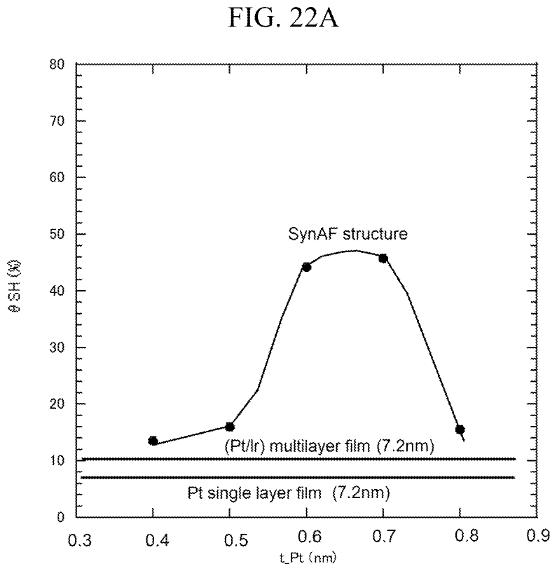

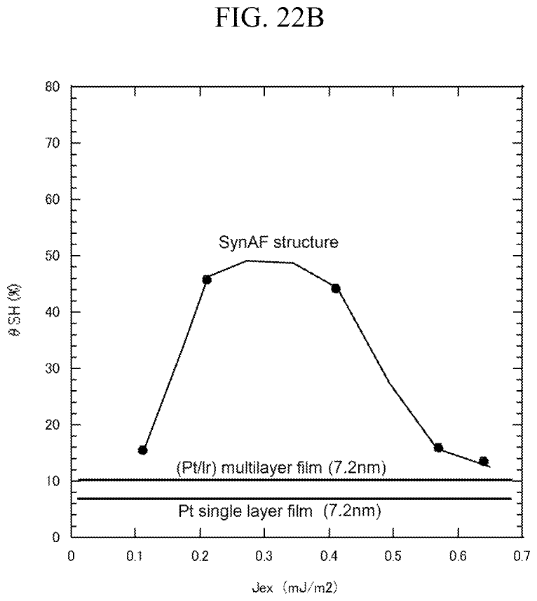

FIG. 22A is a result plotting the dependence of the spin-orbit torque efficiency on the Pt layer thickness regarding Sample 35 to Sample 39. FIG. 22B is a result plotting the dependence of the spin-orbit torque efficiency on the magnitude of interlayer exchange coupling Jₑₓ (mJ/m²) regarding Sample 35 to Sample 39. The horizontal axis of FIG. 22A indicates a Total thickness t_Pt (nm) of the Pt layer 145 and the Pt layer 147, the horizontal axis of FIG. 22B indicates the magnitude of interlayer exchange coupling Jₑₓ (mJ/m²), and the vertical axes of FIG. 22A and FIG. 22B indicate the magnitude of spin-orbit torque efficiency θ_{SH} (%). FIG. 22A and FIG. 22B also illustrate results of cases of a multilayer film of (Pt 1.0 nm/Ir 0.8 nm)₄ and a Pt layer with a thickness of 7.2 nm as Comparative Examples instead of the Pt layer 145/the Ir layer 146/the Pt layer 147. The increase in the thickness of the Pt layer from 0.8 nm to about 1.3 nm increases the magnitude of spin-orbit torque efficiency θ_{SH} (%), and the increase in the thickness of the Pt layer from about 1.3 nm to 1.6 nm reduces the magnitude of spin-orbit torque efficiency θ_{SH} (%). That is, the Pt layer has the thickness at which the magnitudes of spin Hall angle and the spin-orbit torque efficiency become the maxima.

When the Pt layers are used as the non-magnetic layers between which the interlayer coupling layer is interposed, the magnitude of spin-orbit torque efficiency is higher than those of the multilayer film of (Pt 1.0 nm/Ir 0.8 nm)₄ and the Pt layer with the thickness of 7.2 nm when the thickness of the Pt layer is within the range. The thicknesses of the Pt layers 105 and 107 are preferably 0.4 nm or more and 0.8 nm or less, further preferably about 0.5 nm or more and about 0.8 nm or less, and especially preferably 0.55 nm or more and 0.75 nm or less.

### Fifth Embodiment

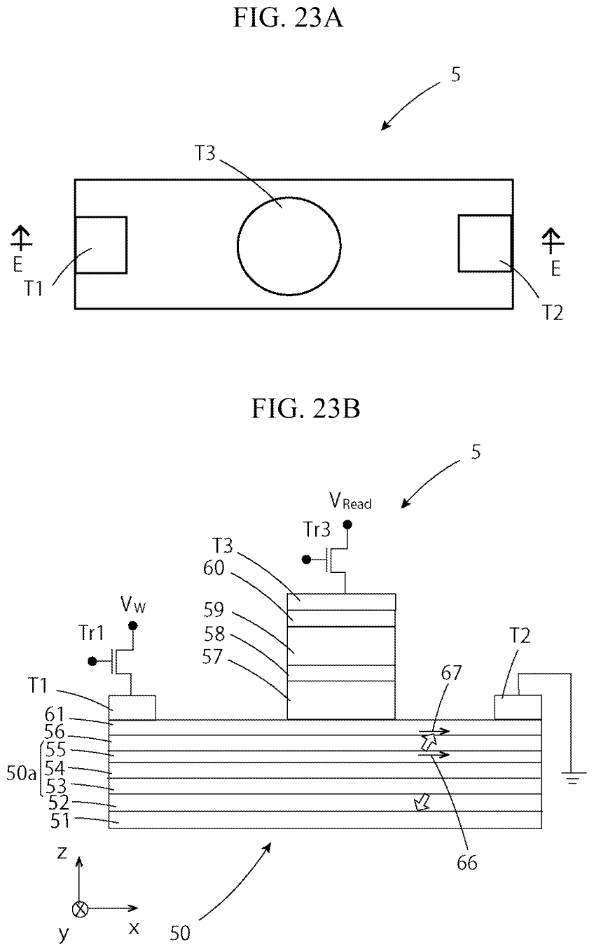

A conductive layer 50 as a magnetic stacked film according to the fifth embodiment includes a third non-magnetic layer 61 on a surface opposite to the antiferromagnetic coupling layers 10a and 40a of the second ferromagnetic layers 16 and 45 in the magnetic stacked films 10 and 40 according to the first to fourth embodiments. The third non-magnetic layer 61 includes a layer made of at least a metal or an alloy (a W alloy, a Cu alloy, a Ta alloy, an Mn alloy, an MnIr alloy, and a TaW alloy) including any one of W, Cu, Ta, and Mn. A magnetoresistive effect element 5 according to the fifth embodiment includes a third non-magnetic layer (for example, the third non-magnetic layer 61 illustrated in FIG. 23B) adjacent to the surface of the recording layers 17, 28, and 28A as an opposite surface of the antiferromagnetic coupling layers 10a and 40a of the second ferromagnetic layers 16 and 45 in the magnetic stacked films 10 and 40 of the magnetoresistive effect elements 1 to 4 according to the first to fourth embodiments. Accordingly, the matters, the materials of the respective layers, the thicknesses, and the like described in the first to fourth embodiments will be omitted to avoid repeated explanation, and the following will representatively describe a case of application to the configuration illustrated in FIG. 1B. A person skilled in the art does not require description of cases of application to the second to fourth embodiments.

FIG. 23A is a plan view of the magnetoresistive effect element according to the fifth embodiment. FIG. 23B is a sectional view taken along the line E-E in FIG. 23A. The magnetoresistive effect element 5 according to the fifth embodiment includes: an underlayer 51 provided on a substrate (not illustrated), a first ferromagnetic layer 52 provided on the underlayer 51, a first non-magnetic layer 53 provided on the first ferromagnetic layer 52, an interlayer coupling layer 54 provided on the first non-magnetic layer 53, a second non-magnetic layer 55 provided on the interlayer coupling layer 54, and a second ferromagnetic layer 56 provided on the second non-magnetic layer 55. That is, the conductive layer 50 is configured as follows. The interlayer coupling layer 54 is interposed between the first non-magnetic layer 53 and the second non-magnetic layer 55 in contact with corresponding upper surface and lower surface of the interlayer coupling layer 54 to configure an antiferromagnetic coupling layer 50a. The first ferromagnetic layer 52 is in contact with the lower surface of the first non-magnetic layer 53, and the second ferromagnetic layer 56 is in contact with the upper surface of the second non-magnetic layer 55. Thus, the first non-magnetic layer 53, the interlayer coupling layer 54, and the second non-magnetic layer 55 are interposed between the first ferromagnetic layer 52 and the second ferromagnetic layer 56, the third non-magnetic layer 61 is configured on the second ferromagnetic layer 56, and the third non-magnetic layer 61 includes a layer made of a metal or an alloy (a W alloy, a Cu alloy, a Ta alloy, an Mn alloy, an MnIr alloy, and a TaW alloy) including at least any one of W, Cu, Ta, and Mn.

In the illustrated configuration, while the third non-magnetic layer 61 is in contact with the upper surface of the second ferromagnetic layer 56, the third non-magnetic layer 61 may be in contact with the lower surface of a recording layer 57. The second ferromagnetic layer 56 in contact with the third non-magnetic layer 61 has a magnetization inclined with respect to the current direction of the conductive layer 50, that is, has a component in the z direction. The third non-magnetic layer 61 after the magnetoresistive effect element 5 is formed (junction isolation) preferably has the thickness of 0.3 nm or more and 2.0 nm or less. This is because when W, Cu, Ta, and Mn after junction isolation do not remain on the second ferromagnetic layer 56, magnetization reversal in a non-magnetic field described below is not observed, and when the third non-magnetic layer 61 is too thick, magnetic interaction between the recording layer 57 and the second ferromagnetic layer 56 weakens, and when SOT magnetization reversal occurs in the first ferromagnetic layer 52 and the second ferromagnetic layer 56, the recording layer 57 of the magnetoresistive effect element 5 is not magnetically switched.

Note that as illustrated in the diagram, on the third non-magnetic layer 61, the recording layer 57 made of the material that allow magnetization reversal is formed, and further, a tunnel barrier layer 58 is provided on the recording layer 57 to be in contact with the recording layer 57. On the tunnel barrier layer 58, a non-magnetic layer 59 as a reference layer is provided. A point that stacking of the recording layer 57, the tunnel barrier layer 58, and the non-magnetic layer 59 configures the magnetoresistive effect element 5 using tunneling anisotropic magnetoresistance effect is similar to the first embodiment.

The fifth embodiment differs in the second non-magnetic layer (a layer made of a metal or an alloy including Pt) 55 and the third non-magnetic layer (a layer made of a metal or an alloy (a W alloy, a Cu alloy, a Ta alloy, an Mn alloy, an MnIr alloy, and a TaW alloy) including any one of W, Cu, Ta, and Mn) 61 provided on upper and lower parts of the second ferromagnetic layer 56. For example, the Co layer as the second ferromagnetic layer 56 is interposed between the second non-magnetic layer (a layer made of a metal or an alloy including Pt) 55 and the third non-magnetic layer (a layer made of a metal or an alloy (a W alloy, a Cu alloy, a Ta alloy, an Mn alloy, an MnIr alloy, and a TaW alloy) including any of W, Cu, Ta, and Mn) 61. Then, even when an external magnetic field is not applied and the first ferromagnetic layer 52 and the second ferromagnetic layer 56 are magnetized to have perpendicular components, flowing current to the conductive layer 50 allows magnetically reversing the first ferromagnetic layer 52 and the second ferromagnetic layer 56 even in a zero external magnetic field. This is considered due to interaction of a magnetic field 66 generated on an interface between the second ferromagnetic layer 56 and the second non-magnetic layer 55 and a magnetic field 67 generated on an interface between the second ferromagnetic layer 56 and the third non-magnetic layer 61. A magnetic field interacted between Co/Pt and any of Co/W, Co/Cu, Co/Ta, and Co/Mn has different signs, and therefore when stacking is performed in the order from the second non-magnetic layer 55, the second ferromagnetic layer 56, and the third non-magnetic layer 61, as indicated by the reference numerals 66 and 67, the magnetic fields are applied in the same direction and the spin of the second ferromagnetic layer 56 is inclined in the x direction. This magnetic field is considered to be DM interaction magnetic field (H_{DMI}) generated from Dzyaloshinskii-Moriya (DM) interaction. The magnetic fields 66 and 67 are H_{DMI}.

As described above, in the fifth embodiment, in the magnetoresistive effect element 1 according to the first embodiment, the third non-magnetic layer 61 is provided on a surface of the recording layer 17 (the recording layer 57 in FIG. 23B) so as to be opposed to the magnetic stacked film 10, for example, between the second ferromagnetic layer 16 and the recording layer 17 (between the second ferromagnetic layer 56 and the recording layer 57 in FIG. 23B).

In the fifth embodiment, in the magnetoresistive effect element 2 according to the second embodiment, the third non-magnetic layer 61 is provided on a surface of the recording layer 28 or 28A so as to be opposed to the magnetic stacked film 10, for example, between the second ferromagnetic layer 16 and the non-magnetic layer 27 illustrated in FIG. 3B and FIG. 3C or between the second ferromagnetic layer 16 and the recording layer 28A illustrated in FIG. 3D.

In the fifth embodiment, in the magnetoresistive effect element 3 according to the third embodiment, the third non-magnetic layer 61 is provided on a surface of the recording layer 17 so as to be opposed to the magnetic stacked film 40, for example, between the second ferromagnetic layer 45 and the recording layer 17 illustrated in FIG. 4B.

In the fifth embodiment, in the magnetoresistive effect element 4 according to the fourth embodiment, the third non-magnetic layer 61 is provided on a surface of the recording layer 28 or 28A so as to be opposed to the magnetic stacked film 40, for example, between the second ferromagnetic layer 45 and the non-magnetic layer 27 illustrated in FIG. 6B and FIG. 6C or between the second ferromagnetic layer 45 and the recording layer 28A illustrated in FIG. 6D.

### Sixth Embodiment

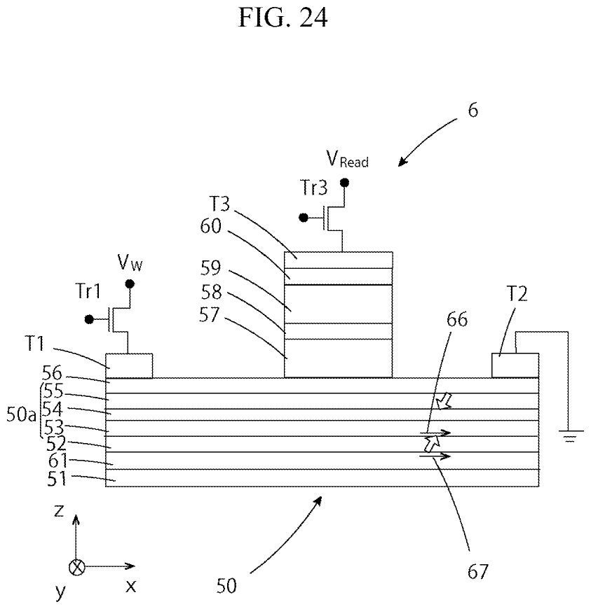

The conductive layer 50 as the magnetic stacked film according to the sixth embodiment includes the third non-magnetic layer 61 on the surface opposite to the antiferromagnetic coupling layers 10a and 40a of the first ferromagnetic layers 12 and 42 in the magnetic stacked films 10 and 40 according to the first to fourth embodiments, and the third non-magnetic layer 61 includes a layer made of a metal or an alloy (a W alloy, a Cu alloy, a Ta alloy, an Mn alloy, an MnIr alloy, and a TaW alloy) including at least any one of W, Cu, Ta, and Mn. A magnetoresistive effect element 6 according to the sixth embodiment includes a third non-magnetic layer (for example, the third non-magnetic layer 61 illustrated in FIG. 24) on an opposite surface of the recording layer as the surface opposite to the antiferromagnetic coupling layers 10a and 40a of the first ferromagnetic layers 12 and 42 in the magnetic stacked films 10 and 40 of the magnetoresistive effect elements 1 to 4 according to the first to fourth embodiments. Accordingly, the matters, the materials of the respective layers, the thicknesses, and the like described in the first to fourth embodiments will be omitted to avoid repeated explanation, and the following will representatively describe a case of application to the configuration illustrated in FIG. 1B. A person skilled in the art does not require description of cases of application to the second to fourth embodiments.

FIG. 24 is a sectional view of a magnetoresistive effect element according to a sixth embodiment. Since the plan view is similar to FIG. 23A, the diagram is omitted. In the sixth embodiment as well, the interlayer coupling layer 54 is interposed between the first non-magnetic layer 53 and the second non-magnetic layer 55 in contact with the corresponding upper surface and lower surface of the interlayer coupling layer 54 to configure the antiferromagnetic coupling layer 50a. The third non-magnetic layer 61 is provided on a lower surface as a surface opposite to the antiferromagnetic coupling layer 50a of the first ferromagnetic layer 52 in the conductive layer 50. The third non-magnetic layer 61 is a layer made of a metal or an alloy (a W alloy, a Cu alloy, a Ta alloy, an Mn alloy, an MnIr alloy, and a TaW alloy) including any one of W, Cu, Ta, and Mn. In the illustrated configuration, the third non-magnetic layer 61 may be in contact with the upper surface of the underlayer 51 and in contact with the lower surface of the first ferromagnetic layer 52. Note that the first ferromagnetic layer 52 and the second ferromagnetic layer 56 have magnetization inclined with respect to the current direction of the conductive layer 50, that is, have a component in the z direction. When the third non-magnetic layer 61 is provided in contact with the lower surface of the first ferromagnetic layer 52, there is no restriction on thickness in particular. However, to keep the antiferromagnetic coupling, the first ferromagnetic layer 52, the first non-magnetic layer 53, the second non-magnetic layer 55, and the second ferromagnetic layer 56 are required to maintain the fcc (111) orientation. In this sense, the use of Cu is the most preferable in this case. The third non-magnetic layer 61 preferably has the thickness of 0.3 nm or more and 2.0 nm or less.

The sixth embodiment differs in the first non-magnetic layer (a layer made of a metal or an alloy including Pt) 53 and the third non-magnetic layer (a layer made of a metal or an alloy (a W alloy, a Cu alloy, a Ta alloy, an Mn alloy, an MnIr alloy, and a TaW alloy) including any one of W, Cu, Ta, and Mn) 61 provided on upper and lower parts of the first ferromagnetic layer 52. For example, the Co layer as the first ferromagnetic layer 52 is interposed between the first non-magnetic layer (a layer made of a metal or an alloy including Pt) 53 and the third non-magnetic layer (a layer made of a metal or an alloy (a W alloy, a Cu alloy, a Ta alloy, an Mn alloy, an MnIr alloy, and a TaW alloy) including any one of W, Cu, Ta, and Mn) 61. Then, even when an external magnetic field is not applied and the first ferromagnetic layer 52 and the second ferromagnetic layer 56 are magnetized to have perpendicular components, flowing current to the conductive layer 50 allows magnetically reversing the first ferromagnetic layer 52 and the second ferromagnetic layer 56 even in a zero external magnetic field. This is considered due to interaction of the magnetic field 66 generated on an interface between the first ferromagnetic layer 52 and the first non-magnetic layer 53 and the magnetic field 67 generated on an interface between the first ferromagnetic layer 52 and the third non-magnetic layer 61. A magnetic field interacted between Co/Pt and any of Co/W, Co/Cu, Co/Ta, and Co/Mn has different signs, and therefore when stacking is performed in the order from the third non-magnetic layer 61, the first ferromagnetic layer 52, and the first non-magnetic layer 53 as indicated by the reference numerals 66 and 67, the magnetic fields are applied in the same direction and the spin of the second ferromagnetic layer 56 is inclined in the x direction. This magnetic field is considered to be DM interaction magnetic field (HDMI) generated from Dzyaloshinskii-Moriya (DM) interaction. The magnetic fields 66 and 67 are H_{DMI}.

As described above, in the sixth embodiment, in the magnetoresistive effect element 1 according to the first embodiment, the third non-magnetic layer 61 is provided on an opposite surface of the recording layer 17 (the recording layer 57 in FIG. 24) so as to be opposed to the magnetic stacked film 10, for example, between the underlayer 11 and the first ferromagnetic layer 12 illustrated in FIG. 1B (between the second ferromagnetic layer 56 and the recording layer 57 in FIG. 24).

In the sixth embodiment, in the magnetoresistive effect element 2 according to the second embodiment, the third non-magnetic layer 61 is provided on an opposite surface of the recording layer 17 so as to be opposed to the magnetic stacked film 10, for example, between the underlayer 11 and the first ferromagnetic layer 12 illustrated in FIG. 3B, FIG. 3C, and FIG. 3D.

In the sixth embodiment, in the magnetoresistive effect element 3 according to the third embodiment, the third non-magnetic layer 61 is provided on an opposite surface of the recording layer 17 so as to be opposed to the magnetic stacked film 40, for example, between the underlayer 41 and the first ferromagnetic layer 42 illustrated in FIG. 4B.

In the sixth embodiment, in the magnetoresistive effect element 4 according to the fourth embodiment, the third non-magnetic layer 61 is provided on a surface of the recording layer 28 or 28A so as to be opposed to the magnetic stacked film 40, for example, between the second ferromagnetic layer 45 and the non-magnetic layer 27 illustrated in FIG. 6B and FIG. 6C or between the second ferromagnetic layer 45 and the recording layer 28A illustrated in FIG. 6D.

### Seventh Embodiment

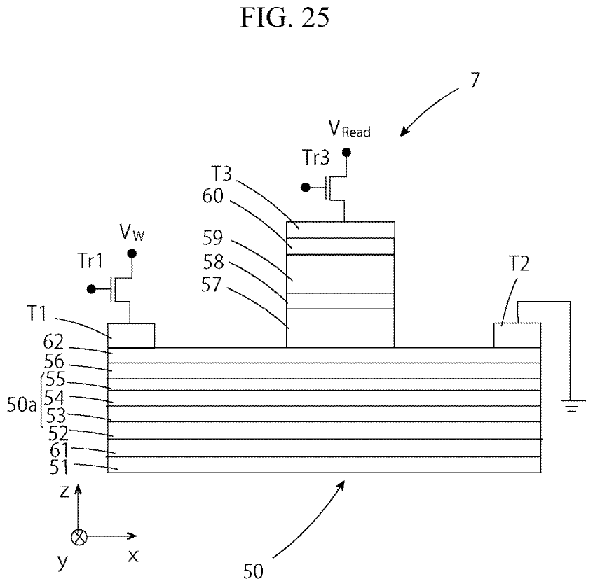

The conductive layer 50 as the magnetic stacked film according to the seventh embodiment includes the third non-magnetic layer 61 on the surface opposite to the antiferromagnetic coupling layers 10a and 40a of the first ferromagnetic layers 12 and 42 in the magnetic stacked films 10 and 40 according to the first to fourth embodiments and a fourth non-magnetic layer 62 on a surface opposite to the antiferromagnetic coupling layers 10a and 40a of the second ferromagnetic layers 16 and 45, and the third non-magnetic layer 61 and the fourth non-magnetic layer 62 include layers made of a metal or an alloy (a W alloy, a Cu alloy, a Ta alloy, an Mn alloy, an MnIr alloy, and a TaW alloy) including at least any one of W, Cu, Ta, and Mn. A magnetoresistive effect element 7 according to the seventh embodiment includes a third non-magnetic layer (for example, the third non-magnetic layer 61 illustrated in FIG. 25) on an opposite surface of the recording layer as the surface opposite to the antiferromagnetic coupling layers 10a and 40a of the first ferromagnetic layers 12 and 42 in the magnetic stacked films 10 and 40 of the magnetoresistive effect elements 1 to 4 according to the first to fourth embodiments, and a fourth non-magnetic layer (for example, the fourth non-magnetic layer 62 illustrated in FIG. 25) on a surface opposite to the antiferromagnetic coupling layers 10a and 40a of the second ferromagnetic layers 16 and 45. Accordingly, the matters, the materials of the respective layers, the thicknesses, and the like described in the first to fourth embodiments will be omitted to avoid repeated explanation, and the following will representatively describe a case of application to the configuration illustrated in FIG. 1B. A person skilled in the art does not require description of cases of application to the second to fourth embodiments.

FIG. 25 is a sectional view of a magnetoresistive effect element according to the seventh embodiment. Since the plan view is similar to FIG. 23A, the diagram is omitted. In the seventh embodiment, the conductive layer 50 constitutes the antiferromagnetic coupling layer 50a by the first non-magnetic layer 53, the interlayer coupling layer 54, and the second non-magnetic layer 55, and includes the third non-magnetic layer (a layer made of a metal or an alloy (a W alloy, a Cu alloy, a Ta alloy, an Mn alloy, an MnIr alloy, and a TaW alloy) including any one of W, Cu, Ta, and Mn) 61 on a lower surface as a surface opposite to the antiferromagnetic coupling layer 50a of the first ferromagnetic layer 52 and the fourth non-magnetic layer (a layer made of a metal or an alloy (a W alloy, a Cu alloy, a Ta alloy, an Mn alloy, an MnIr alloy, and a TaW alloy) including any one of W, Cu, Ta, and Mn) 62 on the upper surface as a surface opposite to the antiferromagnetic coupling layer 50a of the second ferromagnetic layer 56. Note that the first ferromagnetic layer 52 and the second ferromagnetic layer 56 have magnetization inclined with respect to the current direction of the conductive layer 50, that is, have a component in the z direction. The fourth non-magnetic layer (a layer made of a metal or an alloy (a W alloy, a Cu alloy, a Ta alloy, an Mn alloy, an MnIr alloy, and a TaW alloy) of any of W, Cu, Ta, and Mn) 62 after the magnetoresistive effect element 7 is formed (junction isolation) preferably has a thickness of 0.3 nm or more and 2.0 nm or less. This is because when W, Cu, Ta, and Mn do not remain on the second ferromagnetic layer 56 after junction separation, magnetization reversal in a non-magnetic field described below is not observed, and when the fourth non-magnetic layer 62 is too thick, magnetic interaction between the recording layer 57 and the second ferromagnetic layer 56 weakens, and when SOT magnetization reversal occurs in the first ferromagnetic layer 52 and the second ferromagnetic layer 56, the recording layer 57 of the magnetoresistive effect element 7 is not magnetically switched. The third non-magnetic layer (a layer made of a metal or an alloy (a W alloy, a Cu alloy, a Ta alloy, an Mn alloy, an MnIr alloy, and a TaW alloy) including any one of W, Cu, Ta, and Mn) 61 has no restriction on thickness in particular. However, to keep the antiferromagnetic coupling, the first ferromagnetic layer 52, the first non-magnetic layer 53, the second non-magnetic layer 55, and the second ferromagnetic layer 56 are required to maintain the fcc (111) orientation. In this sense, the use of Cu is the most preferable in this case. Note that the third non-magnetic layer 61 and the fourth non-magnetic layer 62 are made of different materials. The third non-magnetic layer 61 preferably has the thickness of 0.3 nm or more and 2.0 nm or less.

The seventh embodiment differs that the first non-magnetic layer (a layer made of a metal or an alloy including Pt) 53 and the third non-magnetic layer (a layer made of a metal or an alloy (a W alloy, a Cu alloy, a Ta alloy, an Mn alloy, an MnIr alloy, and a TaW alloy) including any one of W, Cu, Ta, and Mn) 61 provided on upper and lower parts of the first ferromagnetic layer 52. The second non-magnetic layer (a layer made of a metal or an alloy including Pt) 55 and the fourth non-magnetic layer (a layer made of a metal or an alloy (a W alloy, a Cu alloy, a Ta alloy, an Mn alloy, an MnIr alloy, and a TaW alloy) 62 including any one of W, Cu, Ta, and Mn) provided on upper and lower parts of the second ferromagnetic layer 56 differ. Accordingly, as described in the fifth and sixth embodiments, even when an external magnetic field is not applied and the first ferromagnetic layer 52 and the second ferromagnetic layer 56 are magnetized to have perpendicular components, flowing current to the conductive layer 50 allows magnetically reversing the first ferromagnetic layer 52 and the second ferromagnetic layer 56 even in a zero external magnetic field.

In the seventh embodiment, in the magnetoresistive effect element 2 according to the second embodiment, the third non-magnetic layer 61 is provided on an opposite surface of the recording layer 17 so as to be opposed to the magnetic stacked film 10, for example, between the underlayer 11 and the first ferromagnetic layer 12 illustrated in FIG. 3B, FIG. 3C, and FIG. 3D, and the fourth non-magnetic layer 62 is provided on the surface of the recording layer 28 or 28A so as to be opposed to the magnetic stacked film 10, for example, between the second ferromagnetic layer 16 and the non-magnetic layer 27 illustrated in FIG. 3B and FIG. 3C or between the second ferromagnetic layer 16 and the recording layer 28A illustrated in FIG. 3D.

In the seventh embodiment, in the magnetoresistive effect element 3 according to the third embodiment, the third non-magnetic layer 61 is provided on an opposite surface of the recording layer 17 so as to be opposed to the magnetic stacked film 40, for example, between the underlayer 41 and the first ferromagnetic layer 42 illustrated in FIG. 4B and the fourth non-magnetic layer 62 is provided on a surface of the recording layer 28 or 28A so as to be opposed to the magnetic stacked film 40, for example, between the second ferromagnetic layer 45 and the recording layer 17 illustrated in FIG. 4B.

In the seventh embodiment, in the magnetoresistive effect element 4 according to the fourth embodiment, the third non-magnetic layer 61 is provided on an opposite surface of the recording layer 28 so as to be opposed to the magnetic stacked film 40, for example, between the underlayer 41 and the first ferromagnetic layer 42 illustrated in FIG. 6B, and the fourth non-magnetic layer 62 is provided on a surface of the recording layer 28 or 28A so as to be opposed to the magnetic stacked film 40, for example, between the second ferromagnetic layer 45 and the non-magnetic layer 27 illustrated in FIG. 6B and FIG. 6C or between the second ferromagnetic layer 45 and the recording layer 28A illustrated in FIG. 6D.

In the fifth to seventh embodiments, in the magnetoresistive effect element 1 in the first to fourth embodiments, the third non-magnetic layer 61 and the fourth non-magnetic layer 62 made of a metal or an alloy (a W alloy, a Cu alloy, a Ta alloy, an Mn alloy, an MnIr alloy, and a TaW alloy) including any of W, Cu, Ta, and Mn are interposed between any one of or both of the first ferromagnetic layer 12 or 42 and the magnetic stacked film 10 or 40 and between the second ferromagnetic layer 16 or 45 and the magnetic stacked film 10 or 40. The third non-magnetic layer 61 and the fourth non-magnetic layer 62 can be collectively referred to as a magnetic stacked film.

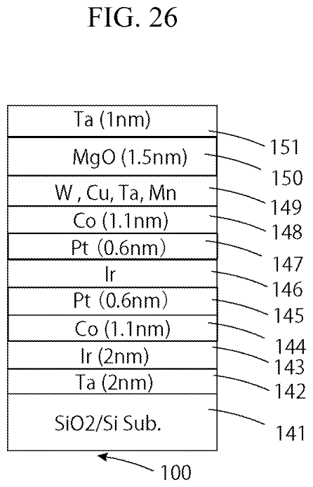

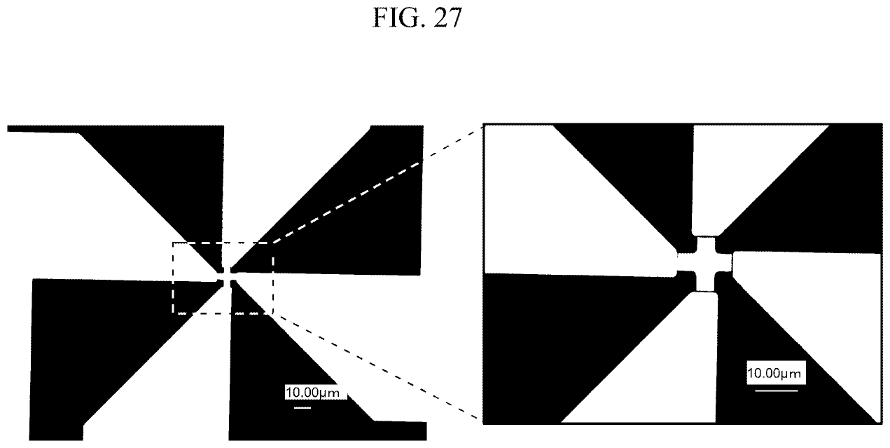

As Demonstrative Example 10, a Hall bar was fabricated similarly to FIG. 18 and FIG. 26 and a measurement system was established. FIG. 26 is a sectional view of Demonstrative Example 10. As illustrated in FIG. 26, Demonstrative Example 10 included: an Si substrate 141 with a thermal oxide film; a Ta layer 142 with a thickness of 2.0 nm provided on the thermal oxide film; an Ir layer 143 with a thickness of 2.0 nm provided on the Ta layer 142; a Co layer 144 with a thickness of 1.1 nm provided on the Ir layer 143; a Pt layer 145 with a thickness of 0.6 nm provided on the Co layer 144; an Ir layer 146 with a thickness of 0.5 nm provided on the Pt layer 145; a Pt layer 147 with a thickness of 0.6 nm provided on the Ir layer 146; a Co layer 148 with a thickness of 1.1 nm provided on the Pt layer 147; a W layer 149 with a thickness of 1.5 nm provided on the Co layer 148; an MgO layer 150 with a thickness of 1.5 nm provided on the W layer 149; and a Ta layer 151 with a thickness of 1.0 nm provided on the MgO layer 151. FIG. 27 is an electron microscope image of the Hall bar fabricated in Demonstrative Example 10, and the right side is an enlarged image at the center of the image.

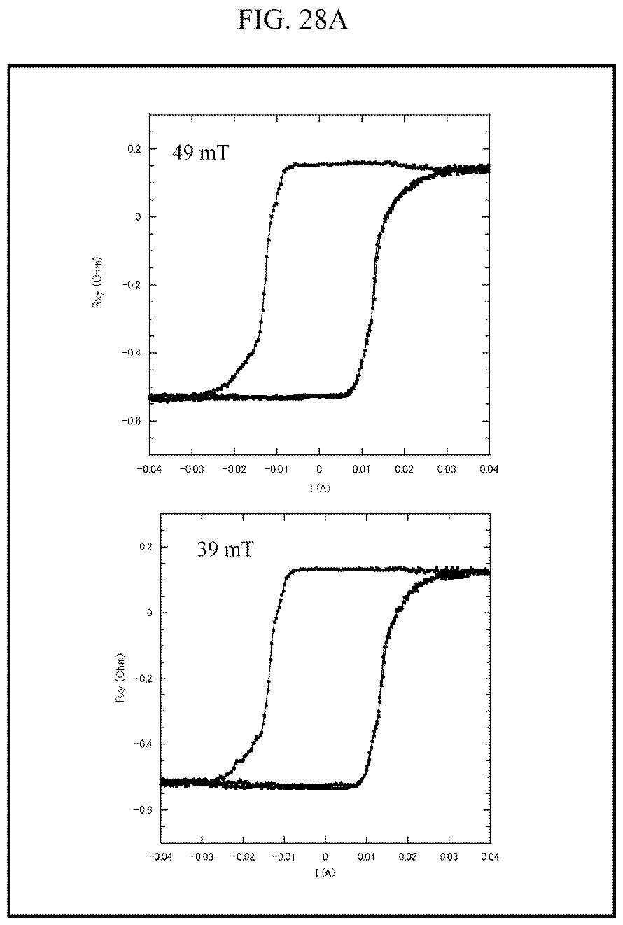

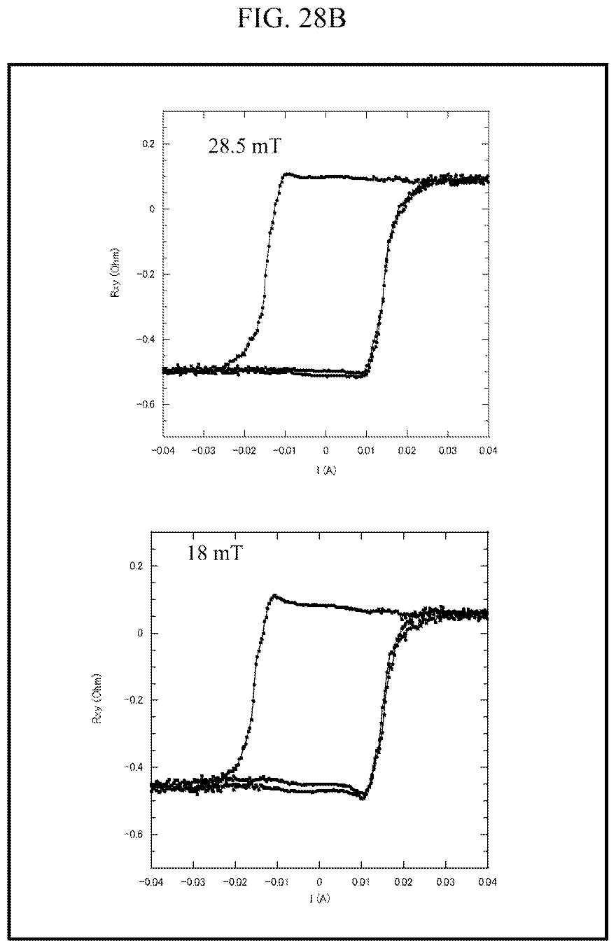

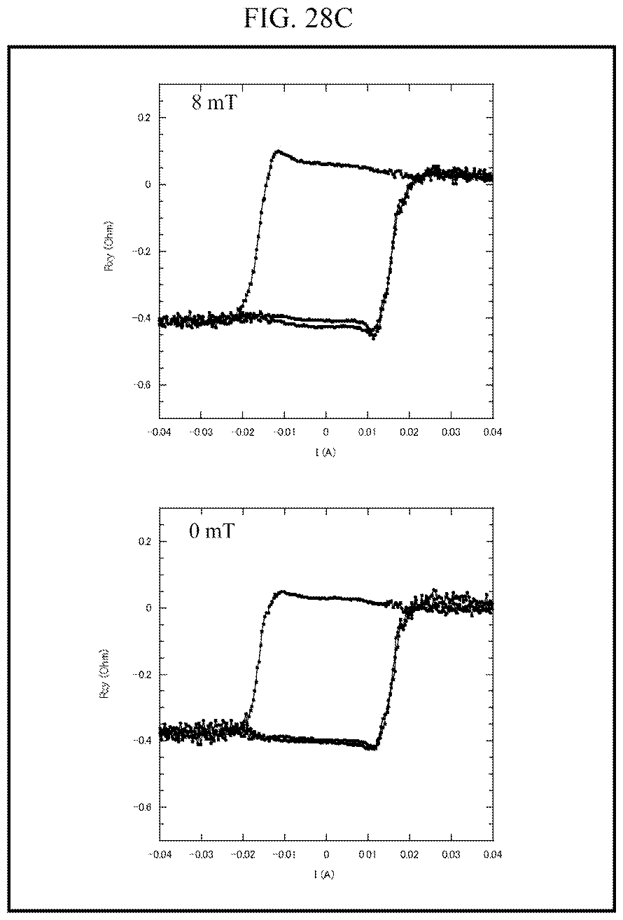

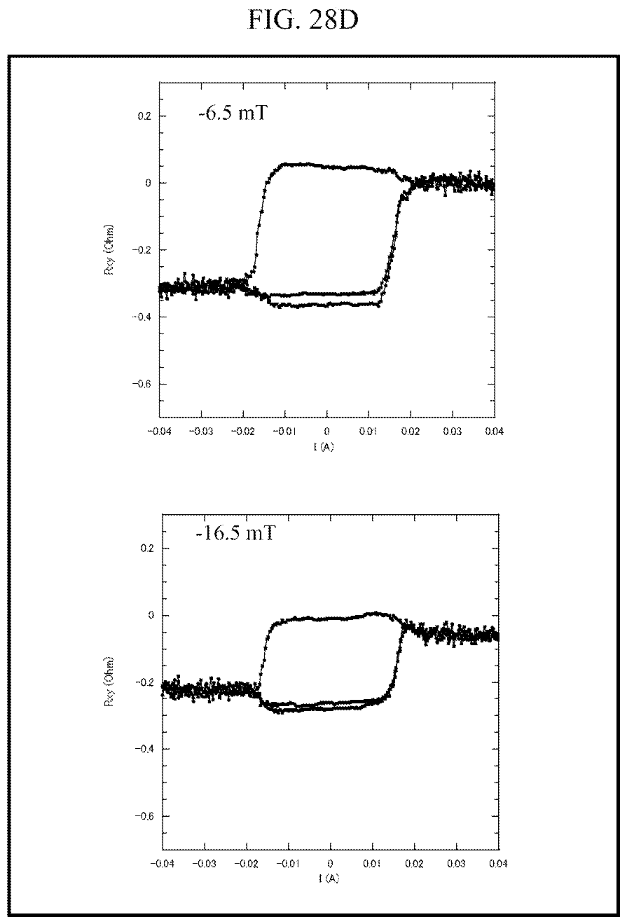

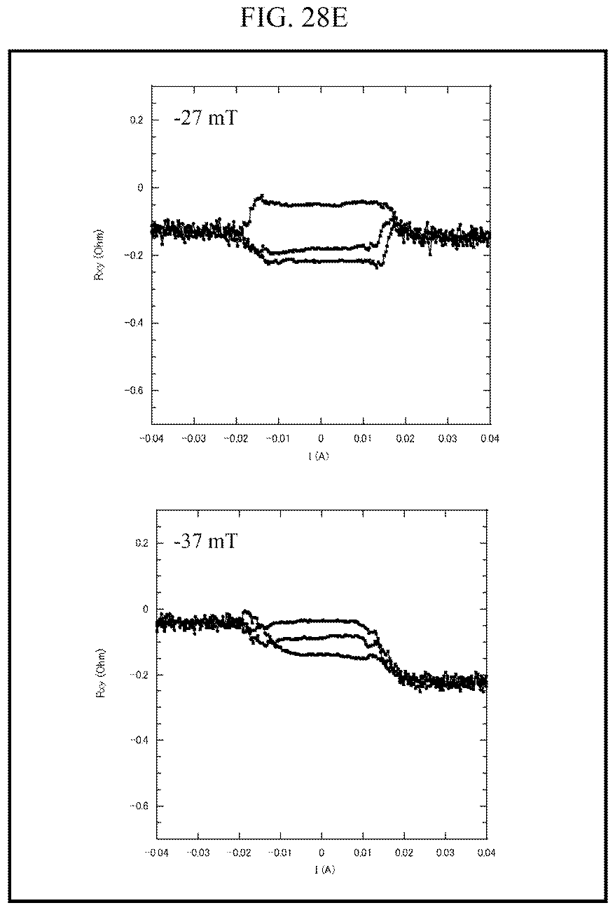

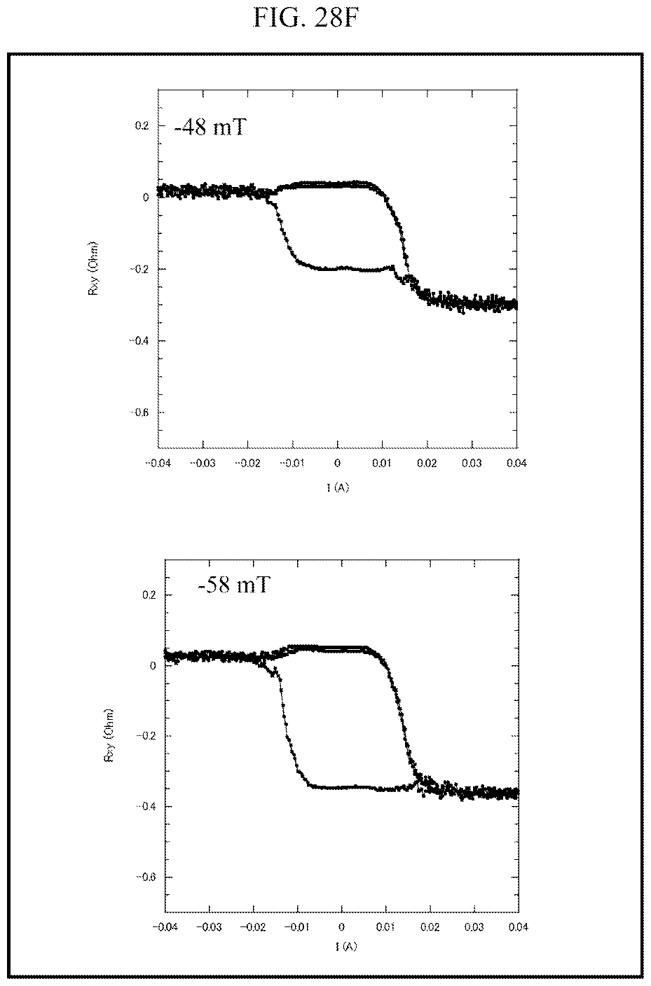

In Demonstrative Example 10, the pulse current I was applied in the y direction to measure a Hall voltage V and a pulse current I dependence of Hall resistivity Rxy (Ω), where Rxy (Ω)=V/I. FIG. 28A to FIG. 28F are diagrams illustrating the dependence of the Hall resistivity Rxy (Ω) on the pulse current in Demonstrative Example 10. The horizontal axis indicates the pulse current I (A) and the vertical axis indicates the Hall resistivity Rxy (Ω). FIG. 28A illustrates a result when applying a pulse current I=200 μsec and a constant external magnetic field Hex=49 mT and 39 mT, respectively, in a direction of the pulse current I (φ=0 degree direction in FIG. 18) during measurement. FIG. 28B illustrates a result when applying the pulse current I=200 μsec and the constant external magnetic field Hex=28.5 mT and 18 mT, respectively, in the direction of the pulse current I (φ=0 degree direction in FIG. 18) during measurement. FIG. 28C illustrates a result when applying the pulse current I=200 μsec and the constant external magnetic field Hex=8 mT and 0 mT, respectively, in the direction of the pulse current I (φ=0 degree direction in FIG. 18) during measurement. FIG. 28D illustrates a result when applying the pulse current I for 200 μsec and the constant external magnetic field Hex=−6.5 mT and −16.5 mT, respectively, in the direction of the pulse current I (φ=0 degree direction in FIG. 18) during measurement. FIG. 28E illustrates a result when applying the pulse current I for 200 μsec and the constant external magnetic field Hex=−27 mT and −37 mT, respectively, in the direction of the pulse current I (φ=0 degree direction in FIG. 18) during measurement. FIG. 28F illustrates a result when applying the pulse current I=200 μsec and the constant external magnetic field Hex=−48 mT and −58 mT, respectively, in the direction of the pulse current I (φ=0 degree direction in FIG. 18) during measurement.

In a case where the external magnetic field was applied at 49 mT, 39 mT, 28.5 mT, 18 mT, 8 mT, 0 mT, −6.5 mT, −16.5 mT, and −27 mT, what observed was an increase of the Hall resistivity Rxy at a certain current value when applying a pulse current in the + direction and a decrease of the Hall resistivity Rxy at a certain current value when applying a pulse current in the − direction, and thus, it has been found that magnetic moments of Co layers 124 and 128 are magnetically switched by the pulse current. It should be especially noted that the magnetic moments of the Co layers 144 and 148 are magnetically switched by the pulse current even when an external magnetic field was not applied.

In a case where the external magnetic field was applied at −37 mT, −48 mT, and −58 mT, what observed was a decrease of the Hall resistivity Rxy at a certain current value when applying a pulse current in the + direction and an increase of the Hall resistivity Rxy at a certain current value when applying a pulse current in the − direction, and thus, it has been found that magnetic moments of the Co layers 144 and 148 are magnetically switched by the pulse current.

Additionally, from these points, it has been found that the DM interaction magnetic field (H_{DMI}) is between-27 mT and −37 mT.

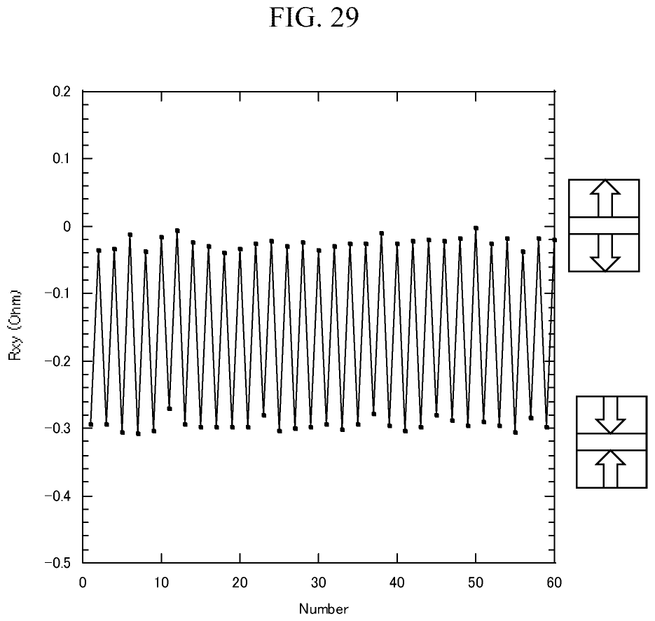

FIG. 29 is a diagram illustrating the dependence of the Hall resistivity Rxy (Ohm) on the number of repetitions when a pulse currents were alternately applied in the ± directions in a magnetic field Hex=0 mT in Demonstrative Example 10. It has been found from FIG. 29 that even when application of the pulse current in the ± directions is repeated, stable magnetization switching occurs.

As Demonstrative Example 11, a Hall bar was fabricated similarly to FIG. 18 and FIG. 26 and a measurement system was established. As illustrated in FIG. 26, Demonstrative Example 11 included: the Si substrate 141 with a thermal oxide film; the Ta layer 142 with a thickness of 2.0 nm provided on the thermal oxide film; the Ir layer 143 with a thickness of 2.0 nm provided on the Ta layer 142; the Co layer 144 with a thickness of 1.1 nm provided on the Ir layer 143; the Pt layer 145 with a thickness of 0.6 nm provided on the Co layer 144; the Ir layer 146 with a thickness of 0.5 nm provided on the Pt layer 145; the Pt layer 147 with a thickness of 0.6 nm provided on the Ir layer 146; the Co layer 148 with a thickness of 1.1 nm provided on the Pt layer 147; a Cu layer 149 with a thickness of 1.0 nm provided on the Co layer 148; the MgO layer 150 with a thickness of 1.5 nm provided on the Cu layer 149; and the Ta layer 151 with a thickness of 1.0 nm provided on the MgO layer 150.

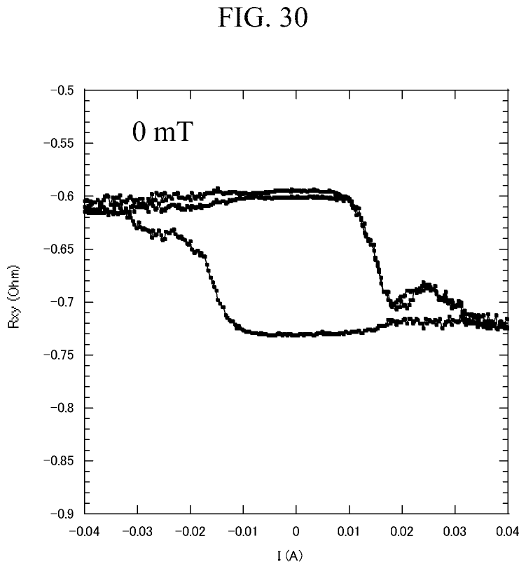

In Demonstrative Example 11, the pulse current I was applied in the y direction to measure a Hall voltage V and a pulse current I dependence of Hall resistivity Rxy (Ω), where Rxy (Ω)=V/I. FIG. 30 is a diagram illustrating a result of the dependence of the Hall resistivity Rxy (Ω) on pulse current in Demonstrative Example 11 when applying the pulse current I=200 μsec and the constant external magnetic field Hex=0 mT during measurement. The horizontal axis indicates the pulse current I (mA) and the vertical axis indicates the Hall resistivity Rxy (Ω).

It has been found that even when an external magnetic field was not applied, what observed was a decrease of the Hall resistivity Rxy at a certain current value when applying a pulse current in the + direction and an increase of the Hall resistivity Rxy at a certain current value when applying a pulse current in the − direction, and thus, it has been found that magnetic moments of the Co layers 144 and 148 are magnetically switched by the pulse current.

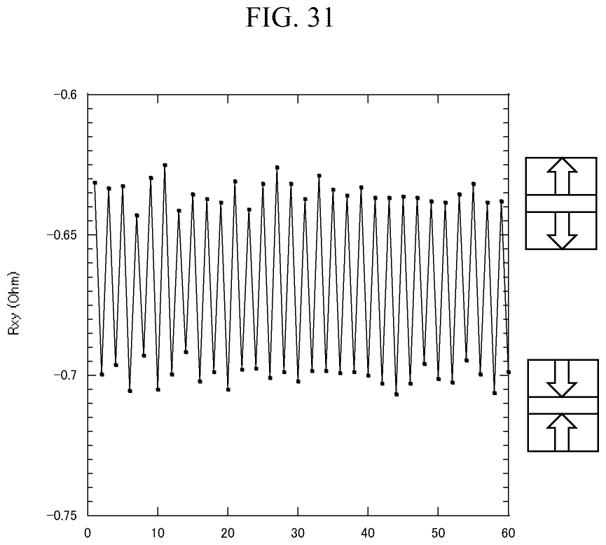

FIG. 31 is a diagram illustrating the dependence of the Hall resistivity Rxy (Ohm) on the number of repetitions when the pulse currents were alternately applied in the ±directions in a magnetic field Hex=0 mT in Demonstrative Example 11. It has been found from FIG. 31 that stable magnetization switching is observed when the pulse current in the ± directions is applied.

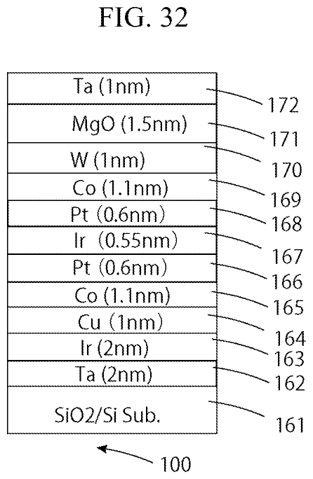

As Demonstrative Example 12, a Hall bar was fabricated similarly to FIG. 18 and a measurement system was established. As illustrated in FIG. 32, Demonstrative Example 12 included: an Si substrate 161 with a thermal oxide film; a Ta layer 162 with a thickness of 2.0 nm provided on the thermal oxide film; an Ir layer 163 with a thickness of 2.0 nm provided on the Ta layer 162; a Cu layer 164 with a thickness of 1.0 mm provided on the Ir layer 163; a Co layer 165 with a thickness of 1.1 nm provided on the Cu layer 164; a Pt layer 166 with a thickness of 0.6 nm provided on the Co layer 165; an Ir layer 167 with a thickness of 0.55 nm provided on the Pt layer 166; a Pt layer 168 with a thickness of 0.6 nm provided on the Ir layer 167; a Co layer 169 with a thickness of 1.1 nm provided on the Pt layer 168; a W layer 170 with a thickness of 1.0 nm provided on the Co layer 169; an MgO layer 171 with a thickness of 1.5 nm provided on the W layer 170; and a Ta layer 172 with a thickness of 1.0 nm provided on the MgO layer 171.

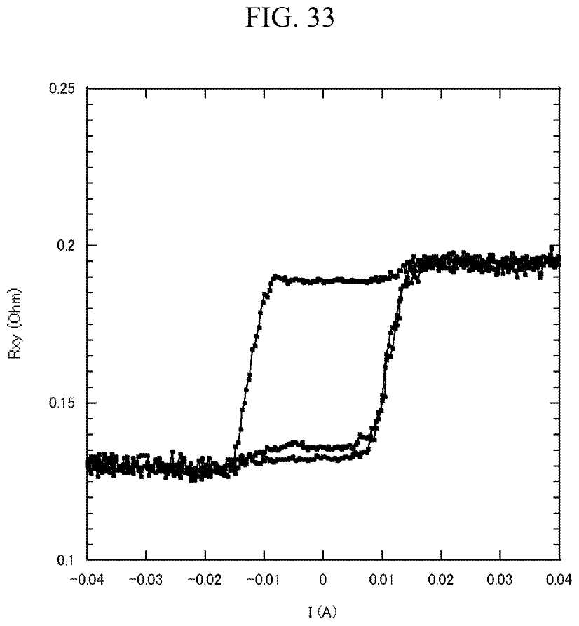

In Demonstrative Example 12, the pulse current I was applied in the y direction to measure a Hall voltage V and a pulse current I dependence of Hall resistivity Rxy (Ω), where Rxy (Ω)=V/I. FIG. 33 is a result plotting the dependence of the Hall resistivity Rxy (Ω) on the pulse current in Comparative Example 12. The horizontal axis indicates the pulse current I (A) and the vertical axis indicates the Hall resistivity Rxy (Ω) During the measurement, the pulse current I was applied for 200 μsec and the constant external magnetic field Hex was not applied. From FIG. 32, what observed was an increase of the Hall resistivity Rxy at a certain current value when applying a pulse current in the + direction and a decrease of the Hall resistivity Rxy at a certain current value when applying a pulse current in the − direction, and thus, it has been found that magnetic moments of the Co layers 165 and 169 are magnetically switched by the pulse current.

As Demonstrative Example 13, a Hall bar was fabricated similarly to FIG. 18 and FIG. 26 and a measurement system was established. As illustrated in FIG. 26, Demonstrative Example 13 included: the Si substrate 141 with a thermal oxide film; the Ta layer 142 with a thickness of 2.0 nm provided on the thermal oxide film; the Ir layer 143 with a thickness of 2.0 nm provided on the Ta layer 142; the Co layer 144 with a thickness of 1.1 nm provided on the Ir layer 143; the Pt layer 145 with a thickness of 0.6 nm provided on the Co layer 144; the Ir layer 146 with a thickness of 0.55 nm provided on the Pt layer 145; the Pt layer 147 with a thickness of 0.6 nm provided on the Ir layer 146; the Co layer 148 with a thickness of 1.1 nm provided on the Pt layer 147; the W layer 149 with a thickness of 0.7 nm provided on the Co layer 148; the MgO layer 150 with a thickness of 1.5 nm provided on the W layer 149; and the Ta layer 151 with a thickness of 1.0 nm provided on the MgO layer 150.

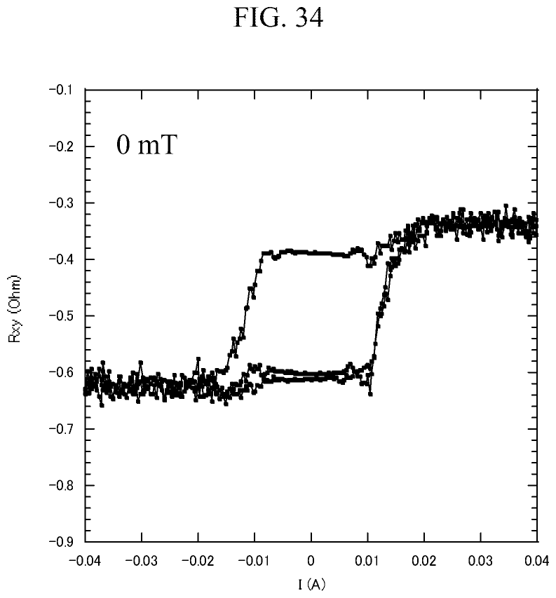

In Demonstrative Example 13, the pulse current I was applied in the y direction to measure a Hall voltage V and a pulse current I dependence of Hall resistivity Rxy (Ω), where Rxy (Ω)=V/I. FIG. 34 is a diagram illustrating the dependence of the Hall resistivity Rxy (Ω) on the pulse current in Demonstrative Example 13. The horizontal axis indicates the pulse current I (A) and the vertical axis indicates the Hall resistivity Rxy (Ω). During the measurement, the pulse current I was applied for 200 μsec and the constant external magnetic field Hex was not applied. From FIG. 34, what observed was an increase of the Hall resistivity Rxy at a certain current value when applying a pulse current in the + direction and a decrease of the Hall resistivity Rxy at a certain current value when applying a pulse current in the − direction, and thus, it has been found that magnetic moments of the Co layers 144 and 148 are magnetically switched by the pulse current.

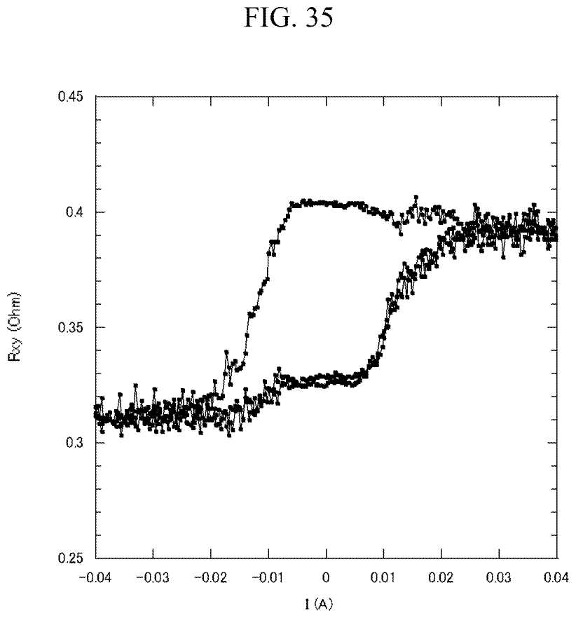

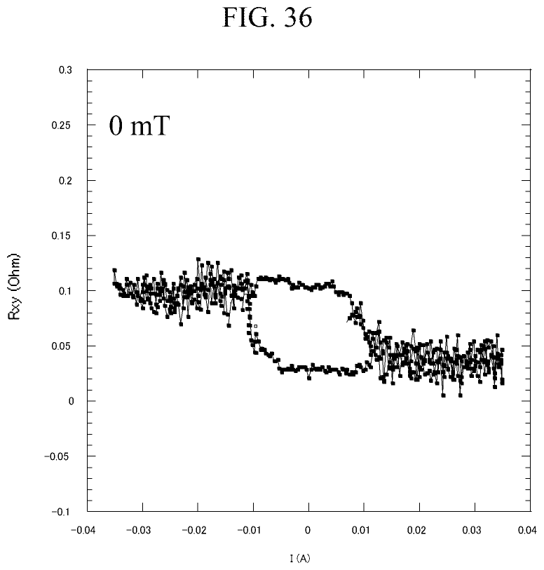

As Demonstrative Example 14, a Hall bar was fabricated similarly to FIG. 18 and FIG. 26 and a measurement system was established. In Demonstrative Example 14, a configuration was similar to that of Demonstrative Example 13 and the thickness of the W layer 149 was 0.3 nm. In Demonstrative Example 14, the pulse current I was applied in the y direction to measure a Hall voltage V and a dependence of the Hall resistivity Rxy (Ω) on the pulse current I, where Rxy (Ω)=V/I. FIG. 35 is a diagram illustrating the dependence of the Hall resistivity Rxy (Ω) on the pulse current in Demonstrative Example 14. The horizontal axis indicates the pulse current I (A) and the vertical axis indicates the Hall resistivity Rxy (Ω). During the measurement, the pulse current I was applied for 200 μsec and the constant external magnetic field Hex was not applied. From FIG. 35, what observed was an increase of the Hall resistivity Rxy at a certain current value when applying a pulse current in the + direction and a decrease of the Hall resistivity Rxy at a certain current value when applying a pulse current in the − direction, and thus, it has been found that magnetic moments of the Co layers 144 and 148 are magnetically switched by the pulse current.

As Demonstrative Example 15, a Hall bar was fabricated similarly to FIG. 18 and FIG. 26 and a measurement system was established. Demonstrative Example 15 is similar to Demonstrative Example 13 except that the Ta layer 149 had the thickness of 1.0 nm while the W layer 149 had the thickness of 0.7 nm in Demonstrative Example 13 in the configuration illustrated in FIG. 26. In Demonstrative Example 15, the pulse current I was applied in the y direction to measure a Hall voltage V and a pulse current I dependence of Hall resistivity Rxy (Ω), where Rxy (Ω)=V/I. FIG. 36 is a diagram illustrating the dependence of the Hall resistivity Rxy (Ω) on the pulse current in Demonstrative Example 15. The horizontal axis indicates the pulse current I (A) and the vertical axis indicates the Hall resistivity Rxy (Ω). During the measurement, the pulse current I was applied for 200 μsec and the constant external magnetic field Hex was not applied. From FIG. 36, what observed was a decrease of the Hall resistivity Rxy at a certain current value when applying a pulse current in the + direction and an increase of the Hall resistivity Rxy at a certain current value when applying a pulse current in the − direction, and thus, it has been found that magnetic moments of the Co layers 144 and 148 are magnetically switched by the pulse current.

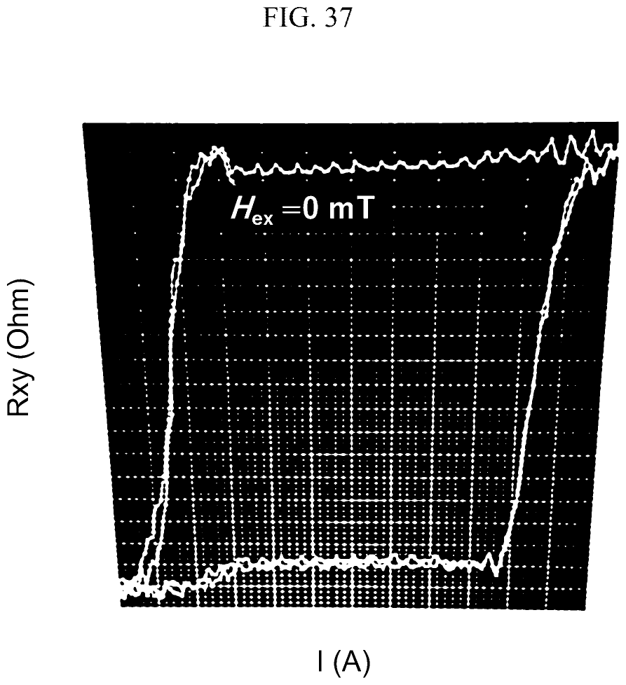

As Demonstrative Example 16, a Hall bar was fabricated similarly to FIG. 18 and FIG. 26 and a measurement system was established. Demonstrative Example 16 is similar to Demonstrative Example 13 except that an Ir₂₂Mn₇₈ layer 129 had the thickness of 2.0 nm while the W layer 129 had the thickness of 0.7 nm in Demonstrative Example 13 in the configuration illustrated in FIG. 26. In Demonstrative Example 16, the pulse current I was applied in the y direction to measure a Hall voltage V and a dependence of the Hall resistivity Rxy (Ω) on the pulse current I, where Rxy (Ω)=V/I. FIG. 37 is a diagram illustrating the dependence of the Hall resistivity Rxy (Ω) on the pulse current I in Demonstrative Example 16. The horizontal axis indicates the pulse current I (A) and the vertical axis indicates the Hall resistivity Rxy (Ω). During the measurement, the pulse current I was applied for 200 μsec and the constant external magnetic field Hex was not applied. From FIG. 37, what observed was an increase of the Hall resistivity Rxy at a certain current value when applying the pulse current in the + direction and a decrease of the Hall resistivity Rxy at a certain current value when applying a pulse current in the − direction, and thus, it has been found that magnetic moments of the Co layers 144 and 148 are magnetically switched by the pulse current.

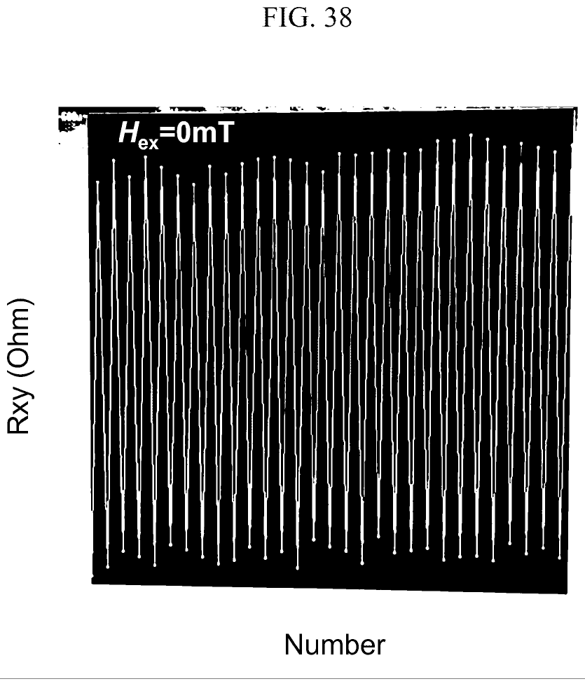

FIG. 38 is a diagram illustrating the dependence of the Hall resistivity Rxy (Ohm) on the number of repetitions when the pulse currents were alternately applied in the ± directions in a magnetic field Hex=0 mT in Demonstrative Example 16. Similarly to FIG. 31, it has been found from FIG. 38 that stable magnetization reversal is observed when the pulse current in the ± directions is applied.

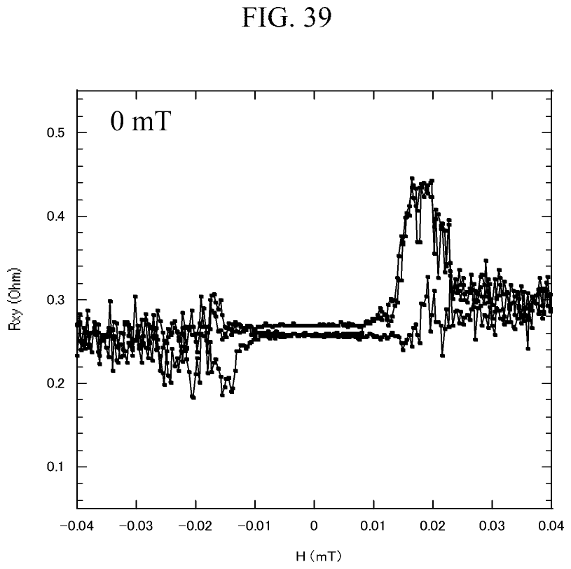

As Comparative Example 3, a Hall bar was fabricated similarly to FIG. 18 and FIG. 26 and a measurement system was established. In the configuration illustrated in FIG. 26, Comparative Example 3 is similar except that the Mo layer 149 had the thickness of 1.0 nm and the Ir layer 126 had the thickness of 0.5 nm. In Comparative Example 3, the pulse current I was applied in the y direction to measure a Hall voltage V and a dependence of the Hall resistivity Rxy (Ω) on the pulse current I, where Rxy (Ω)=V/I. FIG. 39 is a result plotting the dependence of the Hall resistivity Rxy (Ω) on the pulse current in Comparative Example 3. The horizontal axis indicates the pulse current I (A) and the vertical axis indicates the Hall resistivity Rxy (Ω). During the measurement, the pulse current I was applied for 200 μsec and the constant external magnetic field Hex was not applied. From FIG. 39, the magnetization switching of the magnetic moment of the Co layer 144 or 148 by the pulse current was not observed. It has been apparent that at the interface between Pt/Co/Mo, effective Dzyaloshinskii-Moriya (DM) interaction magnetic field (H_{DMI}) is very small similarly to the interface between Pt/Co/Ir.

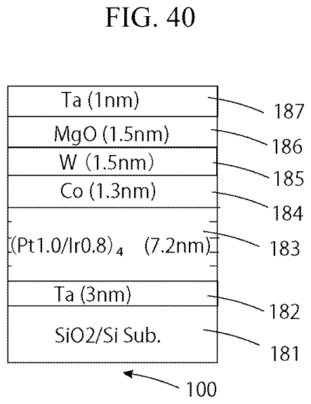

As Comparative Example 4, a Hall bar was fabricated similarly to FIG. 18 and a measurement system was established. FIG. 40 is a sectional view of Comparative Example 4. Comparative Example 4 included: an Si substrate 181 with a thermal oxide film; a Ta layer 182 with a thickness of 3 nm provided on the thermal oxide film; a stacked layer 183 (total film thickness 7.2 nm) of a Pt layer with a thickness of 1.0 nm and an Ir layer with a thickness of 0.8 nm provided on the Ta layer 182; a Co layer 184 with a thickness of 1.3 nm provided on the stacked layer 183; a W layer 185 with a thickness of 1.5 nm provided on the Co layer 184; an MgO layer 186 with a thickness of 1.5 nm provided on the W layer 185; and a Ta layer 187 with a thickness of 1.0 nm provided on the MgO layer 186.

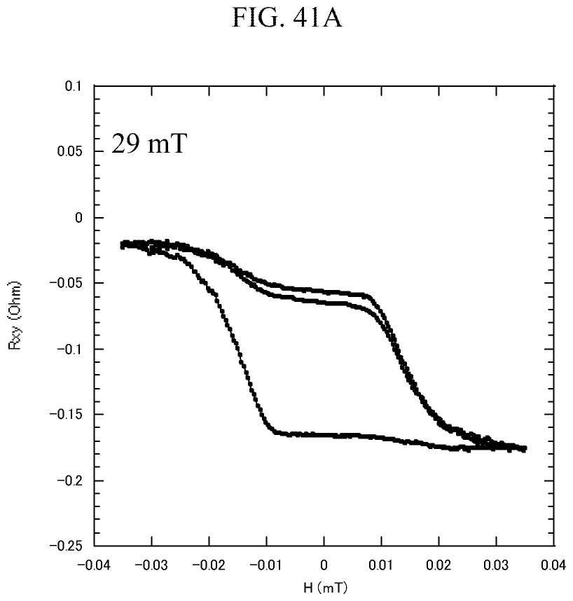

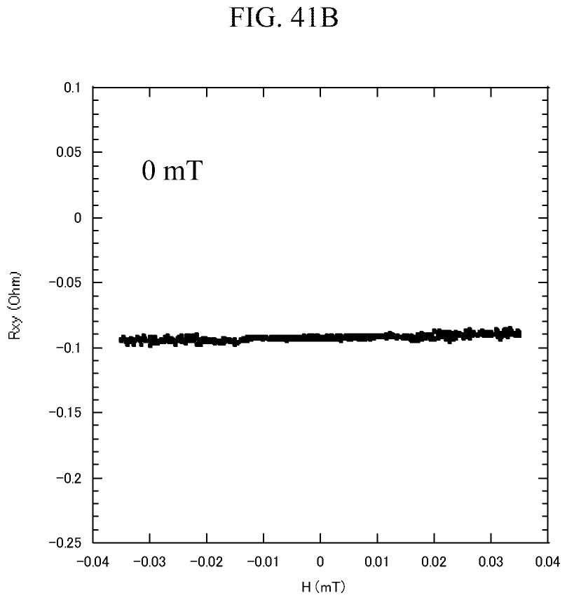

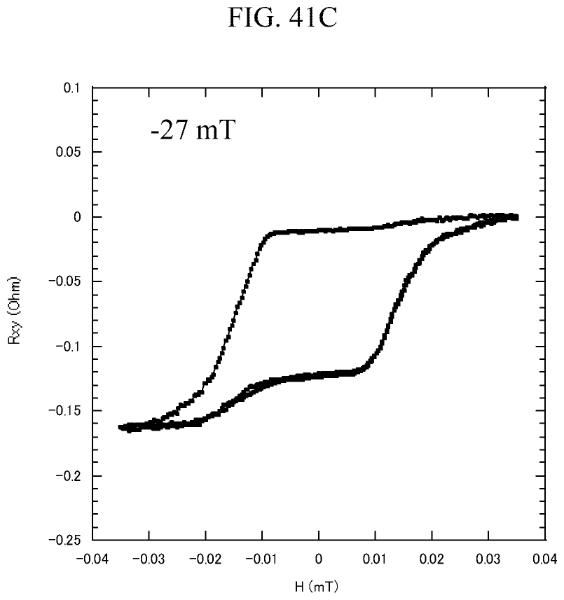

In Comparative Example 4, the pulse current I was applied in the y direction to measure a Hall voltage V and a dependence of the Hall resistivity Rxy (Ω) on the pulse current I, where Rxy (Ω)=V/I. FIG. 41A to FIG. 41C are results plotting the dependence of the Hall resistivity Rxy (Ω) on the pulse current in Comparative Example 4. The horizontal axis indicates the pulse current I (A) and the vertical axis indicates the Hall resistivity Rxy (Ω). FIG. 41A illustrates a result when applying the pulse current I=200 μsec and the constant external magnetic field Hex=29 mT in the direction of the pulse current I (φ=0 degree direction in FIG. 18) during measurement. FIG. 41B illustrates a result when the pulse current I was applied for 200 μsec and the constant external magnetic field Hex was not applied during measurement. FIG. 41C illustrates a result when applying the pulse current I=200 μsec and the constant external magnetic field Hex=−27 mT in the direction of the pulse current I (φ=0 degree direction in FIG. 18) during measurement.

In a case where the external magnetic field was applied at 29 mT, what observed was a decrease of the Hall resistivity Rxy at a certain current value when applying a pulse current in the + direction and an increase of the Hall resistivity Rxy at a certain current value when applying a pulse current in the − direction, and thus, it has been found that a magnetic moment of the Co layer 184 is magnetically switched by the pulse current.

In a case where the external magnetic field was applied at −27 mT, what observed was an increase of the Hall resistivity Rxy at a certain current value when applying a pulse current in the + direction and a decrease of the Hall resistivity Rxy at a certain current value when applying a pulse current in the − direction, and thus, it has been found that a magnetic moment of the Co layer 184 is magnetically switched by the pulse current.

However, when the external magnetic field was not applied, the magnetization reversal of the magnetic moment of the Co layer 184 by the pulse current was not observed. It is considered that with Co of a single layer film, only the magnitude of the effective DM interaction magnetic field (H_{DMI}) is not sufficient for switching the magnetization of the single layer film, different from the case of the structure illustrated in FIG. 23B to FIG. 25.

It has been found from the above-described Demonstrative Examples and Comparative Examples, by providing the third non-magnetic layer 61 made of the metal or the alloy (the W alloy, the Cu alloy, the Ta alloy, the Mn alloy, the MnIr alloy, and the TaW alloy) of at least any of W, Cu, Ta, and Mn on the surface opposite to the antiferromagnetic coupling layer 50a of the second ferromagnetic layer 56 in FIG. 23B, providing the third non-magnetic layer 61 made of the metal or the alloy (the W alloy, the Cu alloy, the Ta alloy, the Mn alloy, the MnIr alloy, and the TaW alloy) of at least any of W, Cu, Ta, and Mn on the surface opposite to the antiferromagnetic coupling layer 50a of the first ferromagnetic layer 52 in FIG. 24, or providing the third non-magnetic layer 61 made of the metal or the alloy (the W alloy, the Cu alloy, the Ta alloy, the Mn alloy, the MnIr alloy, and the TaW alloy) of at least any of W, Cu, Ta, and Mn on the surface opposite to the antiferromagnetic coupling layer 50a of the first ferromagnetic layer 52 in FIG. 25, and providing the fourth non-magnetic layer 62 made of a metal or an alloy (the W alloy, the Cu alloy, the Ta alloy, the Mn alloy, the MnIr alloy, and the TaW alloy) of at least any of W, Cu, Ta, and Mn on the surface opposite to the antiferromagnetic coupling layer 50a of the second ferromagnetic layer 56, even when the external magnetic field is not applied, the first ferromagnetic layer 52 and the second ferromagnetic layer 56 can be magnetically switched by applying the pulse current.

When the second ferromagnetic layer 56 is provided on a surface of the recording layer with respect to the first ferromagnetic layer 52, it is only necessary to provide the third non-magnetic layer 61 on an opposite surface of the recording layer of the first ferromagnetic layer 52 or a surface of the recording layer of the second ferromagnetic layer 56, and it is only necessary to provide the third non-magnetic layer 61 on an opposite surface of the recording layer of the first ferromagnetic layer 52 and provide the fourth non-magnetic layer 62 on a surface of the recording layer of the second ferromagnetic layer 56.

Then, among the first ferromagnetic layer 52 and the second ferromagnetic layer 56, the ferromagnetic layer in contact with the third non-magnetic layer and the fourth non-magnetic layer preferably has a magnetization inclined in the direction of current application of the conductive layer 50. This is because even when the external magnetic field is not applied, the first ferromagnetic layer 52 and the second ferromagnetic layer 56 can be magnetically switched.

Note that respective mutual diffusion layers may be present between the first ferromagnetic layer (for example, the Co layer) 52 and the third non-magnetic layer (a layer of a metal or an alloy including any one of W, Cu, Ta, and Mn) 61 as illustrated in FIG. 24 and FIG. 25, between the second ferromagnetic layer (for example, the Co layer) 56 and the third non-magnetic layer (a layer of a metal or an alloy including any one of W, Cu, Ta, and Mn) 61 as illustrated in FIG. 23B, and between the second ferromagnetic layer (for example, the Co layer) 56 and the fourth non-magnetic layer (a layer of a metal or an alloy of any one of W, Cu, Ta, and Mn) 62 as illustrated in FIG. 25. The mutual diffusion layer has a thickness of 0.2 nm to 0.35 nm.

Conventionally, it has been generally said that the present invention is not appropriate for application since an antiferromagnetic material cannot be controlled in a magnetic field, but the present invention has been made focusing that a spin of an antiferromagnetic material can be controlled by the recent SOT. In the embodiments of the present invention, a crystal is not required as in a CuMnAs system, and as in PU/NiO/Pt, spin injection by spin Hall effect from the above and the below to a NiO layer by separately flowing current to the upper and lower Pt layer is unnecessary. Accordingly, a three-terminal structure in which write current flows to the first terminal and the second terminal separately provided in the magnetic stacked film and the third terminal is provided on the recording layer/the tunnel barrier layer/the fixed layer provided between the first terminal and the second terminal on the magnetic stacked film, and the third terminal is provided to allow flowing read current can be employed.

### REFERENCE SIGNS LIST

1, 2, 3, 4, 5, 6, 7: magnetoresistive effect element
10, 40: magnetic stacked film
10a, 40a, 50a: antiferromagnetic coupling layer
11, 41: underlayer
12, 42, 52: first ferromagnetic layer
13, 44, 53: first non-magnetic layer (non-magnetic layer)
14, 43, 54: interlayer coupling layer (interlayer coupling non-magnetic layer)
15, 55: second non-magnetic layer
16, 45, 56: second ferromagnetic layer
17: recording layer
18: tunnel barrier layer
19: non-magnetic layer
20: cap layer
27: non-magnetic layer
28, 28A: recording layer
29: tunnel barrier layer
30: reference layer
31: non-magnetic layer
32: anchoring layer
33: cap layer
34, 36: Co layer
35: Ir layer
50: conductive layer
61: third non-magnetic layer
62: fourth non-magnetic layer

1-16. (canceled)

17. A magnetoresistive effect element comprising:
a magnetic stacked film;
a recording layer that includes a ferromagnetic layer or an antiferromagnetic layer and is provided on the magnetic stacked film;
a tunnel barrier layer made of an insulating materials and provided on the recording layer; and
a reference layer provided on the tunnel barrier layer,
wherein the magnetic stacked film comprising:
a first ferromagnetic layer;
an antiferromagnetic coupling layer provided on the first ferromagnetic layer; and
a second ferromagnetic layer provided on the antiferromagnetic coupling layer,
wherein the antiferromagnetic coupling layer includes a first non-magnetic layer and an interlayer coupling non-magnetic layer,
wherein the first ferromagnetic layer or the second ferromagnetic layer of the magnetic stacked film and the ferromagnetic layer or the antiferromagnetic layer of the recording layer are coupled by exchange interaction, and
wherein the magnetic stacked film is configured such that respective magnetizations in the first ferromagnetic layer and the second ferromagnetic layer reverse to reverse magnetization of the recording layer with a flow of a write current in a direction intersecting with a stacking direction of the magnetic stacked film.

18. The magnetoresistive effect element according to claim 17,
wherein the reference layer is formed of a non-magnetic layer.

19. The magnetoresistive effect element according to claim 17,
wherein the reference layer includes a magnetic layer in which magnetization is fixed.

20. The magnetoresistive effect element according to claim 17,
wherein the magnetic stacked film includes a third non-magnetic layer on a surface of the recording layer or an opposite surface of the recording layer, and
wherein the third non-magnetic layer is made of a metal or an alloy including at least any one of W, Cu, Ta, and Mn.

21. The magnetoresistive effect element according to claim 17,
wherein the magnetic stacked film includes a third non-magnetic layer on a surface of the recording layer and a fourth non-magnetic layer on an opposite surface of the recording layer, and
wherein the third non-magnetic layer and the fourth non-magnetic layer are made of a metal or an alloy including at least any one of W, Cu, Ta, and Mn.

22. The magnetoresistive effect element according to claim 18,
wherein the magnetic stacked film includes a third non-magnetic layer on a surface of the recording layer or an opposite surface of the recording layer, and
wherein the third non-magnetic layer is made of a metal or an alloy including at least any one of W, Cu, Ta, and Mn.

23. The magnetoresistive effect element according to claim 18,
wherein the magnetic stacked film includes a third non-magnetic layer on a surface of the recording layer and a fourth non-magnetic layer on an opposite surface of the recording layer, and
wherein the third non-magnetic layer and the fourth non-magnetic layer are made of a metal or an alloy including at least any one of W, Cu, Ta, and Mn.

24. The magnetoresistive effect element according to claim 19,
wherein the magnetic stacked film includes a third non-magnetic layer on a surface of the recording layer or an opposite surface of the recording layer, and
wherein the third non-magnetic layer is made of a metal or an alloy including at least any one of W, Cu, Ta, and Mn.

25. The magnetoresistive effect element according to claim 19,
wherein the magnetic stacked film includes a third non-magnetic layer on a surface of the recording layer and a fourth non-magnetic layer on an opposite surface of the recording layer, and
wherein the third non-magnetic layer and the fourth non-magnetic layer are made of a metal or an alloy including at least any one of W, Cu, Ta, and Mn.

26. The magnetoresistive effect element according to claim 17,
wherein the antiferromagnetic coupling layer includes the first non-magnetic layer, the interlayer coupling non-magnetic layer provided on the first non-magnetic layer, and a second non-magnetic layer provided on the interlayer coupling non-magnetic layer.

27. The magnetoresistive effect element according to claim 17,
wherein the first non-magnetic layer is made of a metal or an alloy including Pt.

28. The magnetoresistive effect element according to claim 17,
wherein the interlayer coupling non-magnetic layer is made of a metal or an alloy including at least any one of Ir, Rh, and Ru.

29. A magnetoresistive effect element comprising:
a conductive layer that includes a first ferromagnetic layer, an antiferromagnetic coupling layer provided on the first ferromagnetic layer, and a second ferromagnetic layer provided on the antiferromagnetic coupling layer, the antiferromagnetic coupling layer including a first non-magnetic layer and an interlayer coupling non-magnetic layer;
a recording layer provided on the conductive layer;
a tunnel barrier layer provided on the recording layer; and
a reference layer provided on the tunnel barrier layer,
wherein the conductive layer includes a third non-magnetic layer provided on a surface of the recording layer or an opposite surface of the recording layer, and the third non-magnetic layer is made of a metal or an alloy including at least any one of W, Cu, Ta, and Mn.

30. The magnetoresistive effect element according to claim 29,
wherein any one of the first ferromagnetic layer and the second ferromagnetic layer that is in contact with the third non-magnetic layer has a magnetization inclined in a direction of current application of the conductive layer.

31. The magnetoresistive effect element according to claim 29,
wherein the antiferromagnetic coupling layer includes the first non-magnetic layer, the interlayer coupling non-magnetic layer provided on the first non-magnetic layer, and a second non-magnetic layer provided on the interlayer coupling non-magnetic layer.

32. The magnetoresistive effect element according to claim 29,
wherein the first non-magnetic layer is made of a metal or an alloy including Pt.

33. The magnetoresistive effect element according to claim 29,
wherein the interlayer coupling non-magnetic layer is made of a metal or an alloy including at least any one of Ir, Rh, and Ru.
